(19) United States
(12) Patent Application Publication
(10) Pub. No.: US 2024/0297088 A1
(43) Pub. Date: Sep. 5, 2024

(54) SEMICONDUCTOR DEVICE

(71) Applicant: ROHM CO., LTD., Kyoto-shi (JP)

(72) Inventor: Yuki NAKANO, Kyoto-shi (JP)

(73) Assignee: ROHM CO., LTD., Kyoto-shi (JP)

(21) Appl. No.: 18/654,623

(22) Filed: May 3, 2024

Related U.S. Application Data
(63) Continuation of application No. PCT/JP2022/040500, filed on Oct. 28, 2022.

(30) Foreign Application Priority Data
Nov. 5, 2021 (JP) 2021-181319

(51) Int. Cl. H01L 23/29

(52) U.S. Cl. CPC H01L 23/295

(57) ABSTRACT

A semiconductor device includes a chip that has a main surface, a main surface electrode that is arranged on the main surface, a terminal electrode that is arranged on the main surface electrode, a sealing insulator that covers a periphery of the terminal electrode on the main surface such as to expose a part of the terminal electrode, and that includes a matrix resin and fillers added into the matrix resin such that a ratio of a total cross-sectional area with respect to a unit cross-sectional area is higher than a ratio of a cross-sectional area of the matrix resin with respect to the unit cross-sectional area.

### CROSS-REFERENCE TO RELATED APPLICATIONS

The present application is a bypass continuation of International Patent Application No. PCT/JP2022/040500 filed on Oct. 28, 2022, which claims the benefit of priority to Japanese Patent Application No. 2021-181319 filed on Nov. 5, 2021, the entire contents of each application are hereby incorporated herein by reference.

### BACKGROUND

### 1. Field of the Disclosure

The present disclosure relates to a semiconductor device.

### 2. Description of the Related Art

US20190080976A1 discloses a semiconductor device that includes a semiconductor substrate, an electrode and a protective film. The electrode is formed on the semiconductor substrate. The protective film has a laminated structure that includes an inorganic protective film and an organic protective film and covers the electrode.

### BRIEF DESCRIPTION OF THE DRAWINGS

FIG. 1 is a plan view of a semiconductor device according to a first embodiment.

FIG. 2 is a cross sectional view taken along II-II line shown in FIG. 1.

FIG. 3 is an enlarged plan view showing a principal part of an inner portion of a chip.

FIG. 4 is a cross sectional view taken along IV-IV line shown in FIG. 3.

FIG. 5 is an enlarged cross sectional view showing a peripheral portion of the chip.

FIG. 6 is a plan view showing layout examples of a gate electrode and a source electrode.

FIG. 7 is a plan view showing a layout example of an upper insulating film.

FIG. 8 is a perspective view showing a wafer structure that is to be used at a time of manufacturing.

FIG. 9 is a cross sectional view showing a device region shown in FIG. 8.

FIGS. 10A to 10I are cross sectional views showing a manufacturing method example for the semiconductor device shown in FIG. 1.

FIG. 11 is a plan view showing a semiconductor device according to a second embodiment.

FIG. 12 is a plan view showing a semiconductor device according to a third embodiment.

FIG. 13 is a cross sectional view taken along XIII-XIII line shown in FIG. 12.

FIG. 14 is a circuit diagram showing an electrical configuration of the semiconductor device shown in FIG. 12.

FIG. 15 is a plan view showing a semiconductor device according to a fourth embodiment.

FIG. 16 is a cross sectional view taken along XVI-XVI line shown in FIG. 15.

FIG. 17 is a plan view showing a semiconductor device according to a fifth embodiment.

FIG. 18 is a plan view showing a semiconductor device according to a sixth embodiment.

FIG. 19 is a plan view showing a semiconductor device according to a seventh embodiment.

FIG. 20 is a plan view showing a semiconductor device according to a eighth embodiment.

FIG. 21 is a cross sectional view taken along XXI-XXI line shown in FIG. 20.

FIG. 22 is a cross sectional view showing a modified example of the chip to be applied to each of the embodiments.

FIG. 23 is a cross sectional view showing a modified example of a sealing insulator to be applied to each of the embodiments.

FIG. 24 is a plan view showing a package to which any one of the semiconductor devices according to the first to seventh embodiments is to be incorporated.

FIG. 25 is a plan view showing a package to which the semiconductor devices according to the eighth embodiment is to be incorporated.

FIG. 26 is a perspective view showing a package to which any one of the semiconductor devices according to the first to seventh embodiments and the semiconductor devices according to the eighth embodiment is to be incorporated.

FIG. 27 is an exploded perspective view of the package shown in FIG. 26.

FIG. 28 is a cross sectional view taken along XXVIII-XXVIII line shown in FIG. 26.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference symbols are given to corresponding structures among the attached drawings, and duplicate descriptions thereof shall be omitted or simplified. For the structures whose description have been omitted or simplified, the description given before the omission or simplification shall be applies.

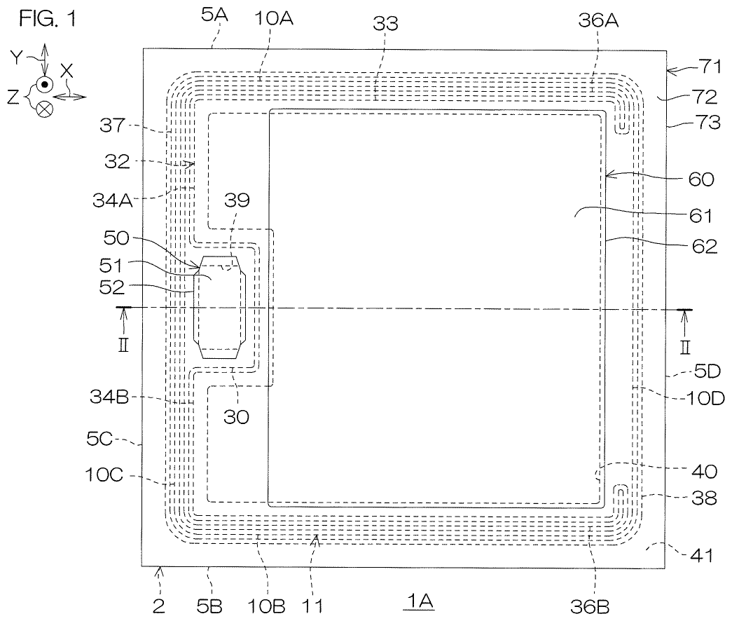

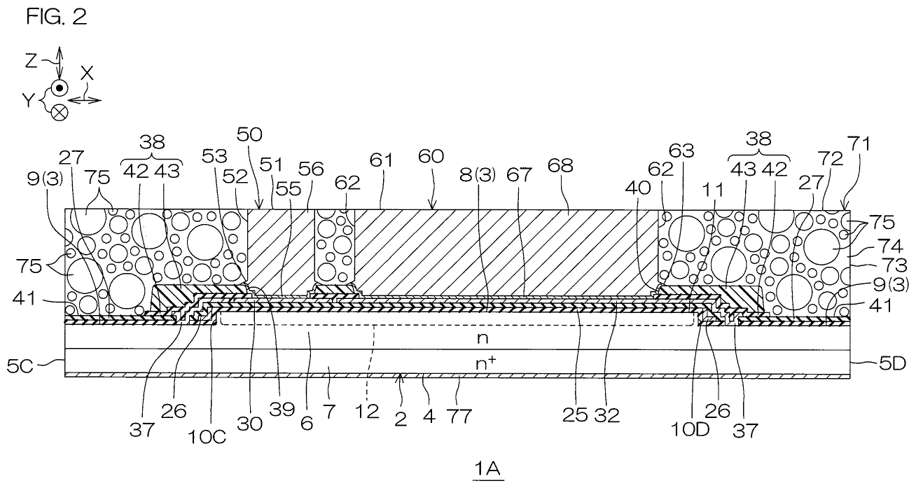

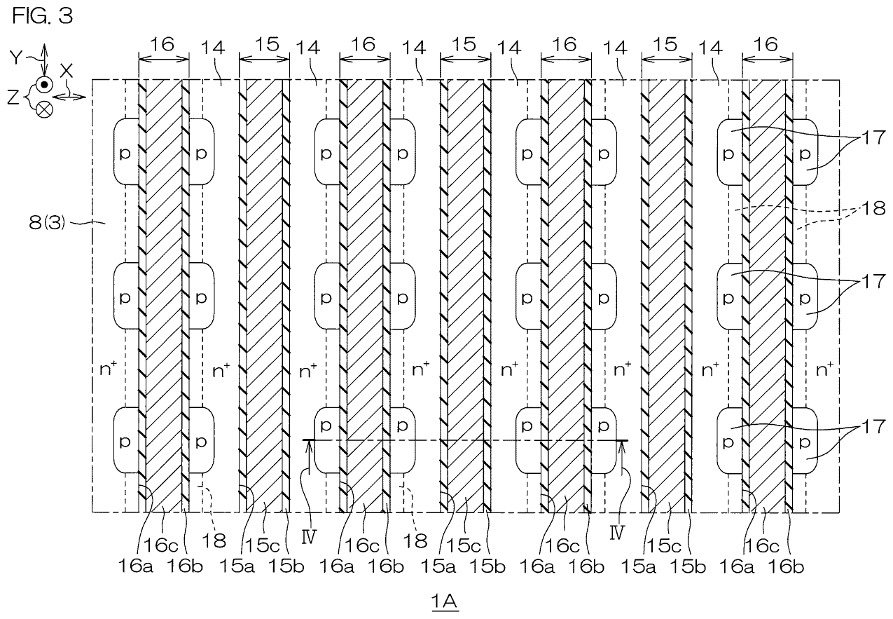

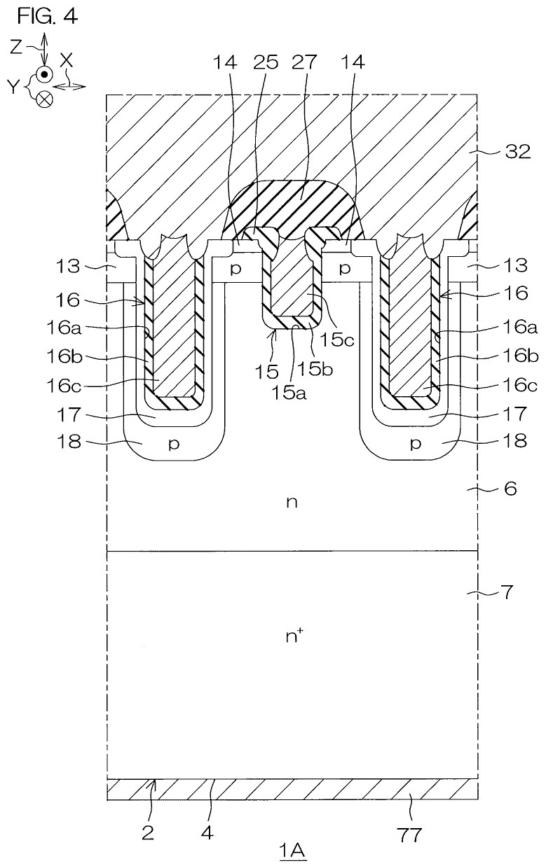

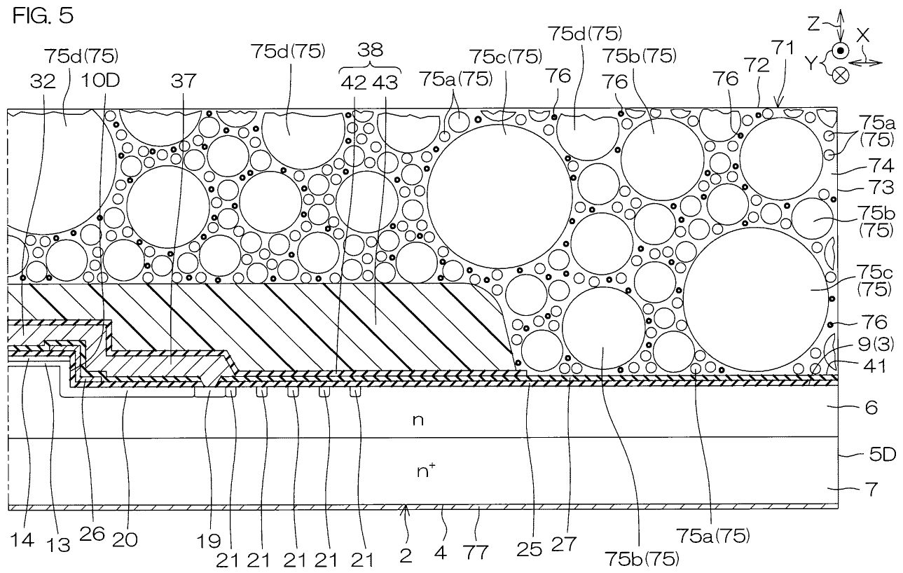

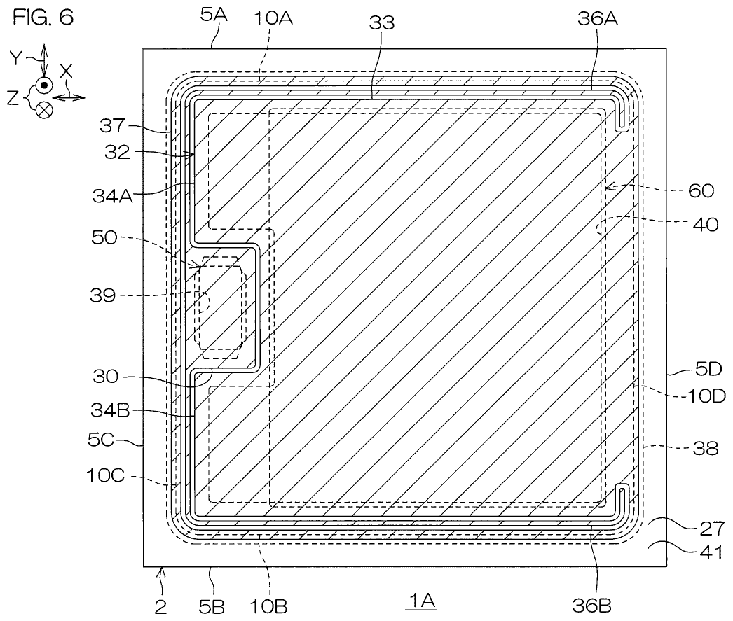

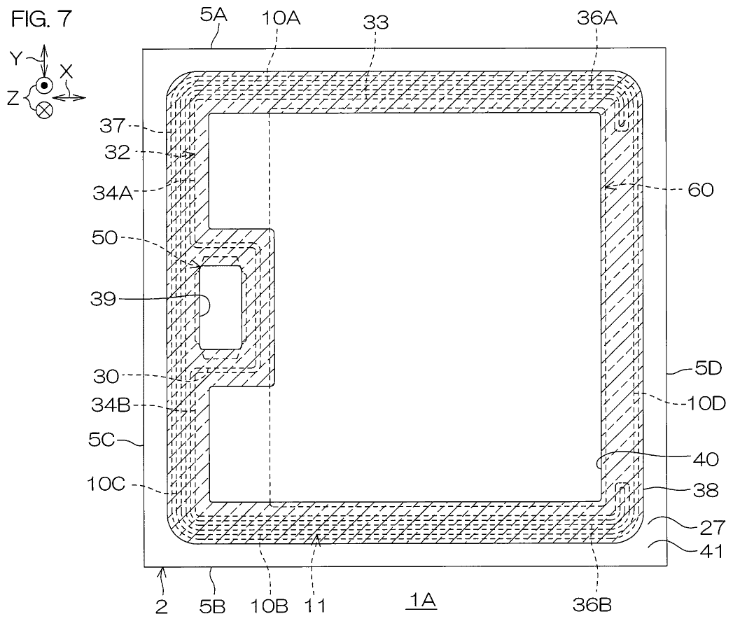

FIG. 1 is a plan view of a semiconductor device 1A according to a first embodiment. FIG. 2 is a cross sectional view taken along II-II line shown in FIG. 1. FIG. 3 is an enlarged plan view showing a principal part of an inner portion of a chip 2. FIG. 4 is a cross sectional view taken along IV-IV line shown in FIG. 3. FIG. 5 is an enlarged cross sectional view showing a peripheral portion of the chip 2. FIG. 6 is a plan view showing layout examples of a gate electrode 30 and a source electrode 32. FIG. 7 is a plan view showing a layout example of an upper insulating film 38.

With reference to FIG. 1 to FIG. 7, the semiconductor device 1A includes a chip 2 that includes a monocrystal of a wide bandgap semiconductor and that is formed in a hexahedral shape (specifically, rectangular parallelepiped shape), in this embodiment. That is, the semiconductor device 1A is a “wide bandgap semiconductor device”. The chip 2 may be referred to as a “semiconductor chip” or a “wide bandgap semiconductor chip”. The wide bandgap semiconductor is a semiconductor having a bandgap exceeding a bandgap of an Si (Silicon). GaN (gallium nitride), SiC (silicon carbide) and C (diamond) are exemplified as the wide bandgap semiconductors.

The chip 2 is an “SiC chip” including an SiC monocrystal of a hexagonal crystal as an example of the wide bandgap semiconductor. That is, the semiconductor device 1A is an “SiC semiconductor device”. The SiC monocrystal of the hexagonal crystal has multiple polytypes including 2H (Hexagonal)-SiC monocrystal, 4H-SiC monocrystal, 6H-SiC monocrystal and the like. In this embodiment, an example in which the chip 2 includes the 4H-SiC monocrystal is to be given, but this does not preclude a choice of other polytypes.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are each formed in a quadrangle shape in plan view as viewed from their normal direction Z (hereinafter, simply referred to as “in plan view”). The normal direction Z is also a thickness direction of the chip 2. The first main surface 3 and the second main surface 4 are preferably formed by a c-plane of the SiC monocrystal, respectively.

In this case, the first main surface 3 is preferably formed by a silicon surface of the SiC monocrystal, and the second main surface 4 is preferably formed by a carbon surface of the SiC monocrystal. The first main surface 3 and the second main surface 4 may each have an off angle inclined with a predetermined angle with respect to the c-plane toward a predetermined off direction. The off direction is preferably an a-axis direction ([11−20] direction) of the SiC monocrystal. The off angle may exceed 0° and be not more than 10°. The off angle is preferably not more than 5°. The second main surface 4 may consist of a ground surface with grinding marks, or may consist of a smooth surface without a grinding mark.

The first side surface 5A and the second side surface 5B extend in a first direction X along the first main surface 3 and oppose in a second direction Y intersecting to (specifically, orthogonal to) the first direction X. The third side surface 5C and the fourth side surface 5D extend in the second direction Y and oppose in the first direction X. The first direction X may be an m-axis direction ([1−100] direction) of the SiC monocrystal, and the second direction Y may be the a-axis direction of the SiC monocrystal. As a matter of course, the first direction X may be the a-axis direction of the SiC monocrystal, and the second direction Y may be the m-axis direction of the SiC monocrystal. The first to fourth side surfaces 5A to 5D may each consist of a ground surface with grinding marks, or may each consist of a smooth surface without a grinding mark.

The chip 2 has a thickness of not less than 5 μm and not more than 250 μm in regard to the normal direction Z. The thickness of the chip 2 may be not more than 100 μm. The thickness of the chip 2 is preferably not more than 50 μm. The thickness of the chip 2 is particularly preferably not more than 40 μm. The first to fourth side surfaces 5A to 5D may each have a length of not less than 0.5 mm and not more than 10 mm in plan view.

The lengths of the first to fourth side surfaces 5A to 5D are preferably not less than 1 mm. The lengths of the first to fourth side surfaces 5A to 5D are particularly preferably not less than 2 mm. That is, the chip 2 preferably has a planar area of not less than 1 mm square (preferably, not less than 2 mm square) and preferably has a thickness of not more than 100 μm (preferably, not more than 50 μm). The lengths of the first to fourth side surfaces 5A to 5D are set in a range of not less than 4 mm and not more than 6 mm, in this embodiment.

The semiconductor device 1A includes a first semiconductor region 6 of an n-type (first conductivity type) that is formed in a region (surface layer portion) on the first main surface 3 side inside the chip 2. The first semiconductor region 6 is formed in a layered shape extending along the first main surface 3 and is exposed from the first main surface 3 and the first to fourth side surfaces 5A to 5D. The first semiconductor region 6 consists of an epitaxial layer (specifically, an SiC epitaxial layer), in this embodiment. The first semiconductor region 6 may have a thickness of not less than 1 μm and not more than 50 μm in regard to the normal direction Z. The thickness of the first semiconductor region 6 is preferably not less than 3 μm and not more than 30 μm. The thickness of the first semiconductor region 6 is particularly preferably not less than 5 μm and not more than 25 μm.

The semiconductor device 1A includes a second semiconductor region 7 of the n-type that is formed in a region (surface layer portion) on the second main surface 4 side inside the chip 2. The second semiconductor region 7 is formed in a layered shape extending along the second main surface 4 and exposes from the second main surface 4 and the first to fourth side surfaces 5A to 5D. The second semiconductor region 7 has an n-type impurity concentration higher than that of the first semiconductor region 6 and is electrically connected to the first semiconductor region 6. The second semiconductor region 7 consists of a semiconductor substrate (specifically, an SiC semiconductor substrate), in this embodiment. That is, the chip 2 has a laminated structure including the semiconductor substrate and the epitaxial layer.

The second semiconductor region 7 may have a thickness of not less than 1 μm and not more than 200 μm, in regard to the normal direction Z. The thickness of the second semiconductor region 7 is preferably not less than 5 μm and not more than 50 μm. The thickness of the second semiconductor region 7 is particularly preferably not less than 5 μm and not more than 20 μm. Considering an error to be occurred to the first semiconductor region 6, the thickness of the second semiconductor region 7 is preferably not less than 10 μm. The thickness of the second semiconductor region 7 is most preferably less than the thickness of the first semiconductor region 6. According to the second semiconductor region 7 having the relatively small thickness, a resistance value (for example, an on-resistance) due to the second semiconductor region 7 can be reduced. As a matter of course, the thickness of the second semiconductor region 7 may exceed the thickness of first semiconductor region 6.

The semiconductor device 1A includes an active surface 8 (active surface), an outer surface 9 (outer surface) and first to fourth connecting surfaces 10A to 10D (connecting surface) that are formed in the first main surface 3. The active surface 8, the outer surface 9 and the first to fourth connecting surfaces 10A to 10D define a mesa portion 11 (plateau) in the first main surface 3. The active surface 8 may be referred to as a “first surface portion”, the outer surface 9 may be referred to as a “second surface portion”, the first to fourth connecting surfaces 10A to 10D may be referred to as “connecting surface portions”. The active surface 8, the outer surface 9 and the first to fourth connecting surfaces 10A to 10D (that is, the mesa portion 11) may be considered as components of the chip 2 (the first main surface 3).

The active surface 8 is formed at an interval inward from a peripheral edge of the first main surface 3 (the first to fourth side surfaces 5A to 5D). The active surface 8 has a flat surface extending in the first direction X and the second direction Y. The active surface 8 is formed in a quadrangle shape having four sides parallel to the first to fourth side surfaces 5A to 5D in plan view, in this embodiment.

The outer surface 9 is positioned outside the active surface 8 and is recessed toward the thickness direction of the chip 2 (the second main surface 4 side) from the active surface 8. Specifically, the outer surface 9 is recessed with a depth less than the thickness of the first semiconductor region 6 such as to expose the first semiconductor region 6. The outer surface 9 extends along the active surface 8 in a band shape and is formed in an annular shape (specifically, a quadrangle annular shape) surrounding the active surface 8 in plan view. The outer surface 9 has a flat surface extending in the first direction X and the second direction Y and is formed substantially parallel to the active surface 8. The outer surface 9 is continuous to the first to fourth side surfaces 5A to 5D.

The first to fourth connecting surfaces 10A to 10D extend in the normal direction Z and connect the active surface 8 and the outer surface 9. The first connecting surface 10A is positioned on the first side surface 5A side, the second connecting surface 10B is positioned on the second side surface 5B side, the third connecting surface 10C is positioned on the third side surface 5C side, and the fourth connecting surface 10D is positioned on the fourth side surface 5D side. The first connecting surface 10A and the second connecting surface 10B extend in the first direction X and oppose in the second direction Y. The third connecting surface 10C and the fourth connecting surface 10D extend in the second direction Y and oppose in the first direction X.

The first to fourth connecting surfaces 10A to 10D may substantially vertically extend between the active surface 8 and the outer surface 9 such that the mesa portion 11 of a quadrangle columnar is defined. The first to fourth connecting surfaces 10A to 10D may be downwardly inclined from the active surface 8 to the outer surface 9 such that the mesa portion 11 of a quadrangle pyramid shape is defined. Thus, the semiconductor device 1A includes the mesa portion 11 that is formed in the first semiconductor region 6 at the first main surface 3. The mesa portion 11 is formed only in the first semiconductor region 6 and is not formed in the second semiconductor region 7.

The semiconductor device 1A includes a MISFET (Metal Insulator Semiconductor Field Effect Transistor) structure 12 that is formed in the active surface 8 (the first main surface 3). In FIG. 2, the MISFET structure 12 is shown simplified by a dashed line. Hereinafter, with reference to FIG. 3 and FIG. 4, a specific structure of the MISFET structure 12 shall be described.

The MISFET structure 12 includes a body region 13 of a p-type (second conductivity type) that is formed in a surface layer portion of the active surface 8. The body region 13 is formed at an interval to the active surface 8 side from a bottom portion of the first semiconductor region 6. The body region 13 is formed in a layered shape extending along the active surface 8. The body region 13 may be exposed from parts of the first to fourth connecting surfaces 10A to 10D.

The MISFET structure 12 includes a source region 14 of the n-type that is formed in a surface layer portion of the body region 13. The source region 14 has an n-type impurity concentration higher than that of the first semiconductor region 6. The source region 14 is formed at an interval to the active surface 8 side from a bottom portion of the body region 13. The source region 14 is formed in a layered shape extending along the active surface 8. The source region 14 may be exposed from a whole region of the active surface 8. The source region 14 may be exposed from parts of the first to fourth connecting surfaces 10A to 10D. The source region 14 forms a channel inside the body region 13 between the first semiconductor region 6 and the source region 14.

The MISFET structure 12 includes a plurality of gate structures 15 that are formed in the active surface 8. The plurality of gate structures 15 arrayed at intervals in the first direction X and each formed in a band shape extending in the second direction Y in plan view. The plurality of gate structures 15 penetrate the body region 13 and the source region 14 such as to reach the first semiconductor region 6. The plurality of gate structures 15 control a reversal and a non-reversal of the channel in the body region 13.

Each of the gate structures 15 includes a gate trench 15a, a gate insulating film 15b and a gate embedded electrode 15c, in this embodiment. The gate trench 15a is formed in the active surface 8 and defines a wall surface of the gate structure 15. The gate insulating film 15b covers the wall surface of the gate trench 15a. The gate embedded electrode 15c is embedded in the gate trench 15a with the gate insulating film 15b interposed therebetween and faces the channel across the gate insulating film 15b.

The MISFET structure 12 includes a plurality of source structures 16 that are formed in the active surface 8. The plurality of source structures 16 are each arranged at a region between a pair of adjacent gate structures 15 in the active surface 8. The plurality of source structures 16 are each formed in a band shape extending in the second direction Y in plan view. The plurality of source structures 16 penetrate the body region 13 and the source region 14 to reach the first semiconductor region 6. The plurality of source structures 16 have depths exceeding depths of the gate structures 15. Specifically, the plurality of source structures 16 has the depths substantially equal to the depth of the outer surface 9.

Each of the source structures 16 includes a source trench 16a, a source insulating film 16b and a source embedded electrode 16c. The source trench 16a is formed in the active surface 8 and defines a wall surface of the source structure 16. The source insulating film 16b covers the wall surface of the source trench 16a. The source embedded electrode 16c is embedded in the source trench 16a with the source insulating film 16b interposed therebetween.

The MISFET structure 12 includes a plurality of contact regions 17 of the p-type that are each formed in a region along the source structure 16 inside the chip 2. The plurality of contact regions 17 have p-type impurity concentration higher than that of the body region 13. Each of the contact regions 17 covers the side wall and the bottom wall of each of the source structures 16, and is electrically connected to the body region 13.

The MISFET structure 12 includes a plurality of well regions 18 of the p-type that are each formed in a region along the source structure 16 inside the chip 2. Each of the well regions 18 may have a p-type impurity concentration higher than that of the body region 13 and less than that of the contact regions 17. Each of the well regions 18 covers the corresponding source structure 16 with the corresponding contact region 17 interposed therebetween. Each of the well regions 18 covers the side wall and the bottom wall of the corresponding source structure 16, and is electrically connected to the body region 13 and the contact regions 17.

With reference to FIG. 5, the semiconductor device 1A includes an outer contact region 19 of the p-type that is formed in a surface layer portion of the outer surface 9. The outer contact region 19 has a p-type impurity concentration higher than that of the body region 13. The outer contact region 19 is formed at intervals from a peripheral edge of the active surface 8 and a peripheral edge of the outer surface 9, and is formed in a band shape extending along the active surface 8 in plan view.

The outer contact region 19 is formed in an annular shape (specifically, a quadrangle annular shape) surrounding the active surface 8 in plan view, in this embodiment. The outer contact region 19 is formed at an interval to the outer surface 9 side from the bottom portion of the first semiconductor region 6. The outer contact region 19 is positioned on the bottom portion side of the first semiconductor region 6 with respect to the bottom walls of the plurality of gate structures 15 (the plurality of source structures 16).

The semiconductor device 1A includes an outer well region 20 of the p-type that is formed in the surface layer portion of the outer surface 9. The outer well region 20 has a p-type impurity concentration less than that of the outer contact region 19. The p-type impurity concentration of the outer well region 20 is preferably substantially equal to the p-type impurity concentration of the well regions 18. The outer well region 20 is formed in a region between the peripheral edge of the active surface 8 and the outer contact region 19, and is formed in a band shape extending along the active surface 8 in plan view.

The outer well region 20 is formed in an annular shape (specifically, a quadrangle annular shape) surrounding the active surface 8 in plan view, in this embodiment. The outer well region 20 is formed at an interval to the outer surface 9 side from the bottom portion of the first semiconductor region 6. The outer well region 20 may be formed deeper than the outer contact region 19. The outer well region 20 is positioned on the bottom portion side of the first semiconductor region 6 with respect to the plurality of gate structures 15 (the plurality of source structures 16).

The outer well region 20 is electrically connected to the outer contact region 19. The outer well region 20 extends toward the first to fourth connecting surfaces 10A to 10D side from the outer contact region 19 side, and covers the first to fourth connecting surfaces 10A to 10D, in this embodiment. The outer well region 20 is electrically connected to the body region 13 in the surface layer portion of the active surface 8.

The semiconductor device 1A includes at least one (preferably, not less than 2 and not more than 20) field region 21 of the p-type that is formed in a region between the peripheral edge of the outer surface 9 and the outer contact region 19 in the surface layer portion of the outer surface 9. The semiconductor device 1A includes five field regions 21, in this embodiment. The plurality of field regions 21 relaxes an electric field inside the chip 2 at the outer surface 9. A number, a width, a depth, a p-type impurity concentration, etc., of the field region 21 are arbitrary, and various values can be taken depending on the electric field to be relaxed.

The plurality of field regions 21 are arrayed at intervals from the outer contact region 19 side to the peripheral edge side of the outer surface 9. The plurality of field regions 21 are each formed in a band shape extending along the active surface 8 in plan view. The plurality of field regions 21 are each formed in an annular shape (specifically, a quadrangle annular shape) surrounding the active surface 8 in plan view, in this embodiment. Thus, the plurality of field regions 21 are each formed as an FLR (Field Limiting Ring) region.

The plurality of field regions 21 are formed at intervals to the outer surface 9 side from the bottom portion of the first semiconductor region 6. The plurality of field regions 21 are positioned on the bottom portion side of the first semiconductor region 6 with respect to the bottom walls of the plurality of gate structures 15 (the plurality of source structures 16). The plurality of field regions 21 may be formed deeper than the outer contact region 19. The innermost field region 21 may be connected to the outer contact region 19.

The semiconductor device 1A includes a main surface insulating film 25 that covers the first main surface 3. The main surface insulating film 25 may include at least one of a silicon oxide film, a silicon nitride film and a silicon oxynitride film. The main surface insulating film 25 has a single layered structure consisting of the silicon oxide film, in this embodiment. The main surface insulating film 25 particularly preferably includes the silicon oxide film that consists of an oxide of the chip 2.

The main surface insulating film 25 covers the active surface 8, the outer surface 9 and the first to fourth connecting surfaces 10A to 10D. The main surface insulating film 25 covers the active surface 8 such as to be continuous to the gate insulating film 15b and the source insulating film 16b and to expose the gate embedded electrode 15c and the source embedded electrode 16c. The main surface insulating film 25 covers the outer surface 9 and the first to fourth connecting surfaces 10A to 10D such as to cover the outer contact region 19, the outer well region 20 and the plurality of field regions 21.

The main surface insulating film 25 may be continuous to the first to fourth side surfaces 5A to 5D. In this case, an outer wall of the main surface insulating film 25 may consist of a ground surface with grinding marks. The outer wall of the main surface insulating film 25 may form a single ground surface with the first to fourth side surfaces 5A to 5D. As a matter of course, the outer wall of the main surface insulating film 25 may be formed at an interval inward from the peripheral edge of the outer surface 9 and may expose the first semiconductor region 6 from a peripheral edge portion of the outer surface 9.

The semiconductor device 1A includes a side wall structure 26 that is formed on the main surface insulating film 25 such as to cover at least one of the first to fourth connecting surfaces 10A to 10D at the outer surface 9. The side wall structure 26 is formed in an annular shape (a quadrangle annular shape) surrounding the active surface 8 in plan view, in this embodiment. The side wall structure 26 may have a portion that overlaps onto the active surface 8. The side wall structure 26 may include an inorganic insulator or a polysilicon. The side wall structure 26 may be a side wall wiring that is electrically connected to the plurality of source structures 16.

The semiconductor device 1A includes an interlayer insulating film 27 that is formed on the main surface insulating film 25. The interlayer insulating film 27 may include at least one of a silicon oxide film, a silicon nitride film and a silicon oxynitride film. The interlayer insulating film 27 has a single layered structure consisting of the silicon oxide film, in this embodiment.

The interlayer insulating film 27 covers the active surface 8, the outer surface 9 and the first to fourth connecting surfaces 10A to 10D with the main surface insulating film 25 interposed therebetween. Specifically, the interlayer insulating film 27 covers the active surface 8, the outer surface 9 and the first to fourth connecting surfaces 10A to 10D across the side wall structure 26. The interlayer insulating film 27 covers the MISFET structure 12 on the active surface 8 side and covers the outer contact region 19, the outer well region 20 and the plurality of field regions 21 on the outer surface 9 side.

The interlayer insulating film 27 is continuous to the first to fourth side surfaces 5A to 5D, in this embodiment. An outer wall of the interlayer insulating film 27 may consist of a ground surface with grinding marks. The outer wall of the interlayer insulating film 27 may form a single ground surface with the first to fourth side surfaces 5A to 5D. As a matter of course, the outer wall of the interlayer insulating film 27 may be formed at an interval inward from the peripheral edge of the outer surface 9 and may expose the first semiconductor region 6 from the peripheral edge portion of the outer surface 9.

The semiconductor device 1A includes a gate electrode 30 that is arranged on the first main surface 3 (the interlayer insulating film 27). The gate electrode 30 may be referred to as a “gate main surface electrode”. The gate electrode 30 is arranged at an inner portion of the first main surface 3 at an interval from the peripheral edge of the first main surface 3. The gate electrode 30 is arranged on the active surface 8, in this embodiment. Specifically, the gate electrode 30 is arranged on a region adjacent a central portion of the third connecting surface 10C (the third side surface 5C) at the peripheral edge portion of the active surface 8. The gate electrode 30 is formed in a quadrangle shape in plan view, in this embodiment. As a matter of course, the gate electrode 30 may be formed in a polygonal shape other than the quadrangle shape, a circular shape, or an elliptical shape in plan view.

The gate electrode 30 preferably has a planar area of not more than 25% of the first main surface 3. The planar area of the gate electrode 30 may be not more than 10% of the first main surface 3. The gate electrode 30 may have a thickness of not less than 0.5 μm and not more than 15 μm. The gate electrode 30 may include at least one of a Ti film, a TiN film, a W film, an Al film, a Cu film, an Al alloy film, a Cu alloy film and a conductive polysilicon film.

The gate electrode 30 may include at least one of a pure Cu film (Cu film with a purity of not less than 99%), a pure Al film (Al film with a purity of not less than 99%), an AlCu alloy film, an AlSi alloy film and an AlSiCu alloy film. The gate electrode 30 has a laminated structure that includes the Ti film and the Al alloy film (in this embodiment, AlSiCu alloy film) laminated in that order from the chip 2 side, in this embodiment.

The semiconductor device 1A includes a source electrode 32 that is arranged on the first main surface 3 (the interlayer insulating film 27) at an interval from the gate electrode 30. The source electrode 32 may be referred to as a “source main surface electrode”. The source electrode 32 is arranged at an inner portion of the first main surface 3 at an interval from the peripheral edge of the first main surface 3. The source electrode 32 is arranged on the active surface 8, in this embodiment. The source electrode 32 has a body electrode portion 33 and at least one (in this embodiment, a plurality of) drawer electrode portions 34A, 34B, in this embodiment.

The body electrode portion 33 is arrange at a region on the fourth side surface 5D (the fourth connecting surface 10D) side at an interval from the gate electrode 30 and faces the gate electrode 30 in the first direction X, in plan view. The body electrode portion 33 is formed in a polygonal shape (specifically, quadrangle shape) that has four sides parallel to the first to fourth side surfaces 5A to 5D in plan view, in this embodiment.

The plurality of drawer electrode portions 34A, 34B include a first drawer electrode portion 34A on one side (the first side surface 5A side) and a second drawer electrode portion 34B on the other side (the second side surface 5B side). The first drawer electrode portion 34A is drawn out from the body electrode portion 33 onto a region located on one side (the first side surface 5A side) of the second direction Y with respect to the gate electrode 30, and faces the gate electrode 30 in the second direction Y, in plan view.

The second drawer electrode portion 34B is drawn out from the body electrode portion 33 onto a region located on the other side (the second side surface 5B side) of the second direction Y with respect to the gate electrode 30, and faces the gate electrode 30 in the second direction Y, in plan view. That is, the plurality of drawer electrode portions 34A, 34B sandwich the gate electrode 30 from both sides of the second direction Y, in plan view.

The source electrode 32 (the body electrode portion 33 and the drawer electrode portions 34A, 34B) penetrates the interlayer insulating film 27 and the main surface insulating film 25, and is electrically connected to the plurality of source structures 16, the source region 14 and the plurality of well regions 18. As a matter of course, the source electrode 32 does not may have the drawer electrode portions 34A, 34B and may consist only of the body electrode portion 33.

The source electrode 32 has a planar area exceeding the planar are of the gate electrode 30. The planar area of the source electrode 32 is preferably not less than 50% of the first main surface 3. The planar are of the source electrode 32 is particularly preferably not less than 75% of the first main surface 3. The source electrode 32 may have a thickness of not less than 0.5 μm and not more than 15 μm. The source electrode 32 may include at least one of a Ti film, a TiN film, a W film, an Al film, a Cu film, an Al alloy film, a Cu alloy film and a conductive polysilicon film.

The source electrode 32 may include at least one of a pure Cu film (Cu film with a purity of not less than 99%), a pure Al film (Al film with a purity of not less than 99%), an AlCu alloy film, an AlSi alloy film and an AlSiCu alloy film. The source electrode 32 has a laminated structure that includes the Ti film and the Al alloy film (in this embodiment, AlSiCu alloy film) laminated in that order from the chip 2 side, in this embodiment. The source electrode 32 preferably has the same conductive material as that of the gate electrode 30.

The semiconductor device 1A includes at least one (in this embodiment, a plurality of) gate wirings 36A, 36B that are drawn out from the gate electrode 30 onto the first main surface 3 (the interlayer insulating film 27). The plurality of gate wirings 36A, 36B preferably include the same conductive material as that of the gate electrode 30. The plurality of gate wirings 36A, 36B cover the active surface 8 and do not cover the outer surface 9, in this embodiment. The plurality of gate wirings 36A, 36B are drawn out into a region between the peripheral edge of the active surface 8 and the source electrode 32 and each extends in a band shape along the source electrode 32 in plan view.

Specifically, the plurality of gate wirings 36A, 36B include a first gate wiring 36A and a second gate wiring 36B. The first gate wiring 36A is drawn out from the gate electrode 30 into a region on the first side surface 5A side in plan view. The first gate wiring 36A includes a portion extending as a band shape in the second direction Y along the third side surface 5C and a portion extending as a band shape in the first direction X along the first side surface 5A. The second gate wiring 36B is drawn out from the gate electrode 30 into a region on the second side surface 5B side in plan view. The second gate wiring 36B includes a portion extending as a band shape in the second direction Y along the third side surface 5C and a portion extending as a band shape in the first direction X along the second side surface 5B.

The plurality of gate wirings 36A, 36B intersect (specifically, perpendicularly intersect) both end portions of the plurality of gate structures 15 at the peripheral edge portion of the active surface 8 (the first main surface 3). The plurality of gate wirings 36A, 36B penetrate the interlayer insulating film 27 and are electrically connected to the plurality of gate structures 15. The plurality of gate wirings 36A, 36B may be directly connected to the plurality of gate structures 15, or may be electrically connected to the plurality of gate structures 15 via a conductor film.

The semiconductor device 1A includes a source wiring 37 that is drawn out from the source electrode 32 onto the first main surface 3 (the interlayer insulating film 27). The source wiring 37 preferably includes the same conductive material as that of the source electrode 32. The source wiring 37 is formed in a band shape extending along the peripheral edge of the active surface 8 at a region located on the outer surface 9 side than the plurality of gate wirings 36A, 36B. The source wiring 37 is formed in an annular shape (specifically, a quadrangle annular shape) surrounding the gate electrode 30, the source electrode 32 and the plurality of gate wirings 36A, 36B in plan view, in this embodiment.

The source wiring 37 covers the side wall structure 26 with the interlayer insulating film 27 interposed therebetween and is drawn out from the active surface 8 side to the outer surface 9 side. The source wiring 37 preferably covers a whole region of the side wall structure 26 over an entire circumference. The source wiring 37 penetrates the interlayer insulating film 27 and the main surface insulating film 25 on the outer surface 9 side, and has a portion connected to the outer surface 9 (specifically, the outer contact region 19). The source wiring 37 may penetrate the interlayer insulating film 27 and may be electrically connected to the side wall structure 26.

The semiconductor device 1A includes an upper insulating film 38 that selectively covers the gate electrode 30, the source electrode 32, the plurality of gate wirings 36A, 36B and the source wiring 37. The upper insulating film 38 has a gate opening 39 exposing an inner portion of the gate electrode 30 and covers a peripheral edge portion of the gate electrode 30 over an entire circumference. The gate opening 39 is formed in a quadrangle shape in plan view, in this embodiment.

The upper insulating film 38 has a source opening 40 exposing an inner portion of the source electrode 32 and covers a peripheral edge portion of the source electrode 32 over an entire circumference. The source opening 40 is formed in a polygonal shape along the source electrode 32 in plan view, in this embodiment. The upper insulating film 38 covers whole regions of the plurality of gate wirings 36A, 36B and a whole region of the source wiring 37.

The upper insulating film 38 covers the side wall structure 26 with the interlayer insulating film 27 interposed therebetween, and is drawn out from the active surface 8 side to the outer surface 9 side. The upper insulating film 38 is formed at an interval inward from the peripheral edge of the outer surface 9 (the first to fourth side surfaces 5A to 5D) and covers the outer contact region 19, the outer well region 20 and the plurality of field regions 21. The upper insulating film 38 defines a dicing street 41 with the peripheral edge of the outer surface 9.

The dicing street 41 is formed in a band shape extending along the peripheral edge of the outer surface 9 (the first to fourth side surfaces 5A to 5D) in plan view. The dicing street 41 is formed in an annular shape (specifically, a quadrangle annular shape) surrounding the inner portion of the first main surface 3 (the active surface 8) in plan view, in this embodiment. The dicing street 41 exposes the interlayer insulating film 27, in this embodiment.

As a matter of course, in a case in which the main surface insulating film 25 and the interlayer insulating film 27 expose the outer surface 9, the dicing street 41 may expose the outer surface 9. The dicing street 41 may have a width of not less than 1 μm and not more than 200 μm. The width of the dicing street 41 is a width in a direction orthogonal to an extending direction of the dicing street 41. The width of the dicing street 41 is preferably not less than 5 μm and not more than 50 μm.

The upper insulating film 38 preferably has a thickness exceeding the thickness of the gate electrode 30 and the thickness of the source electrode 32. The thickness of the upper insulating film 38 is preferably less than the thickness of the chip 2. The thickness of the upper insulating film 38 may be not less than 3 μm and not more than 35 μm. The thickness of the upper insulating film 38 is preferably not more than 25 μm.

The upper insulating film 38 has a laminated structure that includes an inorganic insulating film 42 and an organic insulating film 43 laminated in that order form the chip 2 side, in this embodiment. The upper insulating film 38 may include at least one of the inorganic insulating film 42 and the organic insulating film 43, and does not necessarily have to include the inorganic insulating film 42 and the organic insulating film 43 at the same time. The inorganic insulating film 42 selectively covers the gate electrode 30, the source electrode 32, the plurality of gate wirings 36A, 36B and the source wiring 37, and defines a part of the gate opening 39, a part of the source opening 40 and a part of the dicing street 41.

The inorganic insulating film 42 may include at least one of a silicon oxide film, a silicon nitride film and a silicon oxynitride film. The inorganic insulating film 42 preferably includes an insulating material different from that of the interlayer insulating film 27. The inorganic insulating film 42 preferably includes the silicon nitride film. The inorganic insulating film 42 preferably has a thickness less than the thickness of the interlayer insulating film 27. The thickness of the inorganic insulating film 42 may be not less than 0.1 μm and not more than 5 μm.

The organic insulating film 43 selectively covers the inorganic insulating film 42, and defines a part of the gate opening 39, a part of the source opening 40 and a part of the dicing street 41. Specifically, the organic insulating film 43 partially exposes the inorganic insulating film 42 in a wall surface of the gate opening 39. Also, the organic insulating film 43 partially exposes the inorganic insulating film 42 in a wall surface of the source opening 40. Also, the organic insulating film 43 partially exposes the inorganic insulating film 42 in a wall surface of the dicing street 41.

As a matter of course, the organic insulating film 43 may cover the inorganic insulating film 42 such that the inorganic insulating film 42 does not expose from the wall surface of the gate opening 39. The organic insulating film 43 may cover the inorganic insulating film 42 such that the inorganic insulating film 42 does not expose from the wall surface of the source opening 40. The organic insulating film 43 may cover the inorganic insulating film 42 such that the inorganic insulating film 42 does not expose from the wall surface of the dicing street 41. In those cases, the organic insulating film 43 may cover a whole region of the inorganic insulating film 42.

The organic insulating film 43 preferably consists of a resin film other than a thermosetting resin. The organic insulating film 43 may consist of a translucent resin or a transparent resin. The organic insulating film 43 may consist of a negative type photosensitive resin film or a positive type photosensitive resin film. The organic insulating film 43 preferably consists of a polyimide film, a polyamide film or a polybenzoxazole film. The organic insulating film 43 includes the polybenzoxazole film, in this embodiment.

The organic insulating film 43 preferably has a thickness exceeding the thickness of the inorganic insulating film 42. The thickness of the organic insulating film 43 preferably exceeds the thickness of the interlayer insulating film 27. The thickness of the organic insulating film 43 particularly preferably exceeds the thickness of the gate electrode 30 and the thickness of the source electrode 32. The thickness of the organic insulating film 43 may be not less than 3 μm and not more than 30 μm. The thickness of the organic insulating film 43 is preferably not more than 20 μm.

The semiconductor device 1A includes a gate terminal electrode 50 that is arranged on the gate electrode 30. The gate terminal electrode 50 is erected in a columnar shape on a portion of the gate electrode 30 that is exposed from the gate opening 39. The gate terminal electrode 50 has an area less than the area of the gate electrode 30 in plan view and is arranged on the inner portion of the gate electrode 30 at an interval from the peripheral edge of the gate electrode 30.

The gate terminal electrode 50 has a gate terminal surface 51 and a gate terminal side wall 52. The gate terminal surface 51 flatly extends along the first main surface 3. The gate terminal surface 51 may consist of a ground surface with grinding marks. The gate terminal side wall 52 is located on the upper insulating film 38 (specifically, the organic insulating film 43), in this embodiment.

That is, the gate terminal electrode 50 has a portion in contact with the inorganic insulating film 42 and the organic insulating film 43. The gate terminal side wall 52 extends substantially vertically to the normal direction Z. Here, “substantially vertically” includes a mode that extends in the laminate direction while being curved (meandering). The gate terminal side wall 52 includes a portion that faces the gate electrode 30 with the upper insulating film 38 interposed therebetween. The gate terminal side wall 52 preferably consists of a smooth surface without a grinding mark.

The gate terminal electrode 50 has a first protrusion portion 53 that outwardly protrudes at a lower end portion of the gate terminal side wall 52. The first protrusion portion 53 is formed at a region on the upper insulating film 38 (the organic insulating film 43) side than an intermediate portion of the gate terminal side wall 52. The first protrusion portion 53 extends along an outer surface of the upper insulating film 38, and is formed in a tapered shape in which a thickness gradually decreases toward the tip portion from the gate terminal side wall 52 in cross sectional view. The first protrusion portion 53 therefore has a sharp-shaped tip portion with an acute angle. As a matter of course, the gate terminal electrode 50 without the first protrusion portion 53 may be formed.

The gate terminal electrode 50 preferably has a thickness exceeding the thickness of the gate electrode 30. The thickness of the gate terminal electrode 50 is defined by a distance between the gate electrode 30 and the gate terminal surface 51. The thickness of the gate terminal electrode 50 particularly preferably exceeds the thickness of the upper insulating film 38. The thickness of the gate terminal electrode 50 exceeds the thickness of the chip 2, in this embodiment. As a matter of course, the thickness of the gate terminal electrode 50 may be less than the thickness of the chip 2. The thickness of the gate terminal electrode 50 may be not less than 10 μm and not more than 300 μm. The thickness of the gate terminal electrode 50 is preferably not less than 30 μm. The thickness of the gate terminal electrode 50 is particularly preferably not less than 80 μm and not more than 200 μm.

A planar area of the gate terminal electrode 50 is to be adjusted in accordance with the planar area of the first main surface 3. The planar area of the gate terminal electrode 50 is defined by a planar area of the gate terminal surface 51. The planar area of the gate terminal electrode 50 is preferably not more than 25% of the first main surface 3. The planar area of the gate terminal electrode 50 may be not more than 10% of the first main surface 3.

When the first main surface 3 has the planar area of not less than 1 mm square, the planar area of the gate terminal electrode 50 may be not less than 0.4 mm square. The gate terminal electrode 50 may be formed in a polygonal shape (for example, rectangular shape) having a planar area of not less than 0.4 mm×0.7 mm. The gate terminal electrode 50 is formed in a polygonal shape (quadrangle shape with four corners cut out in a rectangular shape) having four sides parallel to the first to fourth side surfaces 5A to 5D in plan view, in this embodiment. As a matter of course, the gate terminal electrode 50 may be formed in a quadrangle shape, a polygonal shape other than the quadrangle shape, a circular shape, or an elliptical shape in plan view.

The gate terminal electrode 50 has a laminated structure that includes a first gate conductor film 55 and a second gate conductor film 56 laminated in that order from the gate electrode 30 side, in this embodiment. The first gate conductor film 55 may include a Ti-based metal film. The first gate conductor film 55 may have a single layered structure consisting of a Ti film or a TiN film. The first gate conductor film 55 may have a laminated structure that includes the Ti film and the TiN film laminated with an arbitrary order.

The first gate conductor film 55 has a thickness less than the thickness of the gate electrode 30. The first gate conductor film 55 covers the gate electrode 30 in a film shape inside the gate opening 39 and is drawn out onto the upper insulating film 38 in a film shape. The first gate conductor film 55 forms a part of the first protrusion portion 53. The first gate conductor film 55 does not necessarily have to be formed and may be omitted.

The second gate conductor film 56 forms a body of the gate terminal electrode 50. The second gate conductor film 56 may include a Cu-based metal film. The Cu-based metal film may be a pure Cu film (Cu film with a purity of not less than 99%) or Cu alloy film. The second gate conductor film 56 includes a pure Cu plating film, in this embodiment. The second gate conductor film 56 preferably has a thickness exceeding the thickness of the gate electrode 30. The thickness of the second gate conductor film 56 particularly preferably exceeds the thickness of the upper insulating film 38. The thickness of the second gate conductor film 56 exceeds the thickness of the chip 2, in this embodiment.

The second gate conductor film 56 covers the gate electrode 30 with the first gate conductor film 55 interposed therebetween inside the gate opening 39, and is drawn out onto the upper insulating film 38 with the first gate conductor film 55 interposed therebetween. The second gate conductor film 56 forms a part of the first protrusion portion 53. That is, the first protrusion portion 53 has a laminated structure that includes the first gate conductor film 55 and the second gate conductor film 56. The second gate conductor film 56 has a thickness exceeding the thickness of the first gate conductor film 55 in the first protrusion portion 53.

The semiconductor device 1A includes a source terminal electrode 60 that is arranged on the source electrode 32. The source terminal electrode 60 is erected in a columnar shape on a portion of the source electrode 32 that is exposed from the source opening 40. The source terminal electrode 60 may have an area less than the area of the source electrode 32 in plan view, and may be arranged on an inner portion of the source electrode 32 at an interval from the peripheral edge of the source electrode 32.

The source terminal electrode 60 is arranged on the body electrode portion 33 of the source electrode 32, and is not arranged on the drawer electrode portions 34A, 34B of the source electrode 32, in this embodiment. A facing area between the gate terminal electrode 50 and the source terminal electrode 60 is thereby reduced. Such a structure is effective in reducing a risk of short-circuit between the gate terminal electrode 50 and the source terminal electrode 60, in a case in which conductive adhesives such as solders and metal pastes are to be adhered to the gate terminal electrode 50 and the source terminal electrode 60. As a matter of course, conductive bonding members such as conductor plates and conducting wires (for example, bonding wires) may be connected to the gate terminal electrode 50 and the source terminal electrode 60. In this case, a risk of short-circuit between the conductive bonding member on the gate terminal electrode 50 side and the conductive bonding member on the source terminal electrode 60 side can be reduced.

The source terminal electrode 60 has a source terminal surface 61 and a source terminal side wall 62. The source terminal surface 61 flatly extends along the first main surface 3. The source terminal surface 61 may consist of a ground surface with grinding marks. The source terminal side wall 62 is located on the upper insulating film 38 (specifically, the organic insulating film 43), in this embodiment.

That is, the source terminal electrode 60 has a portion in contact with the inorganic insulating film 42 and the organic insulating film 43. The source terminal side wall 62 extends substantially vertically to the normal direction Z. Here, “substantially vertically” includes a mode that extends in the laminate direction while being curved (meandering). The source terminal side wall 62 includes a portion that faces the source electrode 32 with the upper insulating film 38 interposed therebetween. The source terminal side wall 62 preferably consists of a smooth surface without a grinding mark.

The source terminal electrode 60 has a second protrusion portion 63 that outwardly protrudes at a lower end portion of the source terminal side wall 62. The second protrusion portion 63 is formed at a region on the upper insulating film 38 (the organic insulating film 43) side than an intermediate portion of the source terminal side wall 62. The second protrusion portion 63 extends along the outer surface of the upper insulating film 38, and is formed in a tapered shape in which a thickness gradually decreases toward the tip portion from the source terminal side wall 62 in cross sectional view. The second protrusion portion 63 therefore has a sharp-shaped tip portion with an acute angle. As a matter of course, the source terminal electrode 60 without the second protrusion portion 63 may be formed.

The source terminal electrode 60 preferably has a thickness exceeding the thickness of the source electrode 32. The thickness of the source terminal electrode 60 is defined by a distance between the source electrode 32 and the source terminal surface 61. The thickness of the source terminal electrode 60 particularly preferably exceeds the thickness of the upper insulating film 38. The thickness of the source terminal electrode 60 exceeds the thickness of the chip 2, in this embodiment.

As a matter of course, the thickness of the source terminal electrode 60 may be less than the thickness of the chip 2. The thickness of the source terminal electrode 60 may be not less than 10 μm and not more than 300 μm. The thickness of the source terminal electrode 60 is preferably not less than 30 μm. The thickness of the source terminal electrode 60 is particularly preferably not less than 80 μm and not more than 200 μm. The thickness of the source terminal electrode 60 is substantially equal to the thickness of the gate terminal electrode 50.

A planar area of the source terminal electrode 60 is to be adjusted in accordance with the planar area of the first main surface 3. The planar area of the source terminal electrode 60 is defined by a planar area of the source terminal surface 61. The planar area of the source terminal electrode 60 preferably exceeds the planar area of the gate terminal electrode 50. The planar area of the source terminal electrode 60 is preferably not less than 50% of the first main surface 3. The planar area of the source terminal electrode 60 is particularly preferably not less than 75% of the first main surface 3.

In a case in which the first main surface 3 has a planar area of not less than 1 mm square, the planar area of the source terminal electrode 60 is preferably not less than 0.8 mm square. In this case, the planar area of each of the source terminal electrode 60 is particularly preferably not less than 1 mm square. The source terminal electrode 60 may be formed in a polygonal shape having a planar area of not less than 1 mm×1.4 mm. The source terminal electrode 60 is formed in a quadrangle shape having four sides parallel to the first to fourth side surfaces 5A to 5D in plan view, in this embodiment. As a matter of course, the source terminal electrode 60 may be formed in a polygonal shape other than the quadrangle shape, a circular shape, or an elliptical shape in plan view.

The source terminal electrode 60 has a laminated structure that includes a first source conductor film 67 and a second source conductor film 68 laminated in that order from the source electrode 32 side, in this embodiment. The first source conductor film 67 may include a Ti-based metal film. The first source conductor film 67 may have a single layered structure consisting of a Ti film or a TiN film. The first source conductor film 67 may have a laminated structure that includes the Ti film and the TiN film with an arbitrary order. The first source conductor film 67 preferably consists of the same conductive material as that of the first gate conductor film 55.

The first source conductor film 67 has a thickness less than the thickness of the source electrode 32. The first source conductor film 67 covers the source electrode 32 in a film shape inside the source opening 40 and is drawn out onto the upper insulating film 38 in a film shape. The first source conductor film 67 forms a part of the second protrusion portion 63. The thickness of the first source conductor film 67 is substantially equal to the thickness of the first gate conductor film 55. The first source conductor film 67 does not necessarily have to be formed and may be omitted.

The second source conductor film 68 forms a body of the source terminal electrode 60. The second source conductor film 68 may include a Cu-based metal film. The Cu-based metal film may be a pure Cu film (Cu film with a purity of not less than 99%) or Cu alloy film. The second source conductor film 68 includes a pure Cu plating film, in this embodiment. The second source conductor film 68 preferably consists of the same conductive material as that of the second gate conductor film 56.

The second source conductor film 68 preferably has a thickness exceeding the thickness of the source electrode 32. The thickness of the second source conductor film 68 particularly preferably exceeds the thickness of the upper insulating film 38. The thickness of the second source conductor film 68 exceeds the thickness of the chip 2, in this embodiment. The thickness of the second source conductor film 68 is substantially equal to the thickness of the second gate conductor film 56.

The second source conductor film 68 covers the source electrode 32 with the first source conductor film 67 interposed therebetween inside the source opening 40, and is drawn out onto the upper insulating film 38 with the first source conductor film 67 interposed therebetween. The second source conductor film 68 forms a part of the second protrusion portion 63. That is, the second protrusion portion 63 has a laminated structure that includes the first source conductor film 67 and the second source conductor film 68. The second source conductor film 68 preferably has a thickness exceeding the thickness of the first source conductor film 67 in the second protrusion portion 63.

The semiconductor device 1A includes a sealing insulator 71 that covers the first main surface 3. The sealing insulator 71 covers a periphery of the gate terminal electrode 50 and a periphery of the source terminal electrode 60 such as to expose a part of the gate terminal electrode 50 and a part of the source terminal electrode 60 on the first main surface 3. Specifically, the sealing insulator 71 covers the active surface 8, the outer surface 9 and the first to fourth connecting surfaces 10A to 10D such as to expose the gate terminal electrode 50 and the source terminal electrode 60.

The sealing insulator 71 exposes the gate terminal surface 51 and the source terminal surface 61 and covers the gate terminal side wall 52 and the source terminal side wall 62. The sealing insulator 71 covers the first protrusion portion 53 of the gate terminal electrode 50 and faces the upper insulating film 38 with the first protrusion portion 53 interposed therebetween, in this embodiment. The sealing insulator 71 suppresses a dropout of the gate terminal electrode 50. Also, the sealing insulator 71 covers the second protrusion portion 63 of the source terminal electrode 60 and faces the upper insulating film 38 with the second protrusion portion 63 interposed therebetween, in this embodiment. The sealing insulator 71 suppresses a dropout of the source terminal electrode 60.

The sealing insulator 71 covers the dicing street 41 at the peripheral edge portion of the outer surface 9. The sealing insulator 71 directly covers the interlayer insulating film 27 at the dicing street 41, in this embodiment. As a matter of course, when the chip 2 (the outer surface 9) or the main surface insulating film 25 is exposed from the dicing street 41, the sealing insulator 71 may directly cover the chip 2 or the main surface insulating film 25 at the dicing street 41.

The sealing insulator 71 has an insulating main surface 72 and an insulating side wall 73. The insulating main surface 72 flatly extends along the first main surface 3. The insulating main surface 72 forms a single flat surface with the gate terminal surface 51 and the source terminal surface 61. The insulating main surface 72 may consist of a ground surface with grinding marks. In this case, the insulating main surface 72 preferably forms a single ground surface with the gate terminal surface 51 and the source terminal surface 61.

The insulating side wall 73 extends toward the chip 2 from a peripheral edge of the insulating main surface 72 and forms a single flat surface with the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The sealing insulator 71 preferably has a thickness exceeding the thickness of the gate electrode 30 and the thickness of the source electrode 32. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm. The thickness of the sealing insulator 71 is substantially equal to the thickness of the gate terminal electrode 50 and the thickness of the source terminal electrode 60.

With reference to FIG. 2 and FIG. 5, the sealing insulator 71 includes a matrix resin 74, a plurality of fillers 75 and a plurality of flexible particles 76 (flexible agent). In FIG. 5, the plurality of flexible particles 76 are each indicated by a thick circle. The sealing insulator 71 is configured such that a mechanical strength is adjusted by the matrix resin 74, the plurality of fillers 75 and the plurality of flexible particles 76.

The sealing insulator 71 may include a coloring material such as carbon black that colors the matrix resin 74. The matrix resin 74 preferably consists of a thermosetting resin. The matrix resin 74 may include at least one of an epoxy resin, a phenol resin and a polyimide resin as an example of the thermosetting resin. The matrix resin 74 includes the epoxy resin, in this embodiment.

The plurality of fillers 75 are added into the matrix resin 74 and are composed of one of or both of spherical objects each consisting of an insulator and indeterminate objects each consisting of an insulator. The indeterminate object has a random shape other than a sphere shape such as a grain shape, a piece shape and a fragment shape. The indeterminate object may have an edge. The plurality of fillers 75 are each composed of the spherical object from a viewpoint of suppressing a damage to be caused by a filler attack, in this embodiment.

The plurality of fillers 75 may include at least one of ceramics, oxides and nitrides. The plurality of fillers 75 each consist of silicon oxide particles (silicon particles), in this embodiment. The plurality of fillers 75 may each have a particle size of not less than 1 nm and not more than 100 μm. The particle sizes of the plurality of fillers 75 are preferably not more than 50 μm.

The sealing insulator 71 preferably include the plurality of fillers 75 differing in the particle sizes. The plurality of fillers 75 may include a plurality of small size fillers 75a (filler), a plurality of medium size fillers 75b (second filler) and a plurality of large size fillers 75c (third filler). The plurality of fillers 75 are preferably added into the matrix resin 74 with a content (density) being in this order of the small size fillers 75a, the medium size fillers 75b and the large size fillers 75c.

The small size fillers 75a may have a thickness less than the thickness of the source electrode 32 (the gate electrode 30). The particle sizes of the small size fillers 75a may be not less than 1 nm and not more than 1 μm. The medium size fillers 75b may have a thickness exceeding the thickness of the source electrode 32 and not more than the thickness of the upper insulating film 38. The particle sizes of the medium size fillers 75b may be not less than 1 μm and not more than 20 μm.

The large size fillers 75c may have a thickness exceeding the thickness of the upper insulating film 38. The plurality of fillers 75 may include at least one large size filler exceeding any one of the thickness of the first semiconductor region 6 (the epitaxial layer), the thickness of the second semiconductor region 7 (the substrate) and the thickness of the chip 2. The particle sizes of the large size fillers 75c may be not less than 20 μm and not more than 100 μm. The particle sizes of the large size fillers 75c are preferably not more than 50 μm.

An average particle size of the plurality of fillers 75 may be not less than 1 μm and not more than 10 μm. The average particle size of the plurality of fillers 75 is preferably not less than 4 μm and not more than 8 μm. As a matter of course, the plurality of fillers 75 does not necessarily have to include all of the small size fillers 75a, the medium size fillers 75b and the large size fillers 75c at the same time, and may be composed of one of or both of the small size fillers 75a and the medium size fillers 75b. For example, in this case, a maximum particle size of the plurality of fillers 75 (the medium size fillers 75b) may be not more than 10 μm.

The sealing insulator 71 may include a plurality of filler fragments 75d each having a broken particle shape in a surface layer portion of the insulating main surface 72 and in a surface layer portion of the insulating side wall 73. The plurality of filler fragments 75d may each be formed by any one of a part of the small size fillers 75a, a part of the medium size fillers 75b and a part of the large size fillers 75c.

The plurality of filler fragments 75d positioned on the insulating main surface 72 side each has a broken portion that is formed along the insulating main surface 72 such as to be oriented to the insulating main surface 72. The plurality of filler fragments 75d positioned on the insulating side wall 73 side each has a broken portion that is formed along the insulating side wall 73 such as to be oriented to the insulating side wall 73. The broken portions of the plurality of filler fragments 75d may be exposed from the insulating main surface 72 and the insulating side wall 73, or may be partially or wholly covered with the matrix resin 74. The plurality of filler fragments 75d do not affect the structures on the chip 2 side, since the plurality of filler fragments 75d are located in the surface layer portions of the insulating main surface 72 and the insulating side wall 73.

The plurality of fillers 75 are added into the matrix resin 74 such that a ratio of a total cross-sectional area with respect to a unit cross-sectional area is higher than a ratio of a cross-sectional area of the matrix resin 74 with respect to the unit cross-sectional area. That is, a density of the plurality of fillers 75 occupying within the sealing insulator 71 is higher than a density of the matrix resin 74 occupying within the sealing insulator 71.

Specifically, the plurality of fillers 75 are added into the matrix resin 74 such that a ratio of a total cross-sectional area with respect to a unit cross-sectional area is not less than 60% and not more than 95%. In other words, the plurality of fillers 75 are added into the matrix resin 74 with a content of not less than 60 wt % and not more than 95 wt %. The total cross-sectional area (filler density) of the plurality of fillers 75 is preferably not less than 75% and not more than 90%. The total cross-sectional area (filler density) of the plurality of fillers 75 is particularly preferably not less than 80%.

When a cross-sectional area of an arbitrary measurement region extracted from a cross-section on which the sealing insulator 71 is exposed is 1, the ratio of the total cross-sectional area of the plurality of fillers 75 is the ratio of the total cross-sectional area of the plurality of fillers 75 included in the measurement region. As a measurement region, a region including the plurality of fillers 75 is selected. For example, a measurement region including not less than 10 fillers 75 and not more than 100 fillers 75 may be selected.

The measurement region may include at least one of the following types, the small size fillers 75a, the medium size fillers 75b, and the large size fillers 75c, but need not necessarily include all of the small size fillers 75a, the medium size fillers 75b, and the large size fillers 75c. As a matter of course, the total cross-sectional area of the plurality of fillers 75 may be obtained from a measurement region including at least two types among the small size fillers 75a, the medium size fillers 75b, and the large size fillers 75c. Alternatively, the total cross-sectional area of the plurality of fillers 75 may be obtained from a measurement region including all of the small size fillers 75a, the medium size fillers 75b, and the large size fillers 75c.

The cross-sectional area of a measurement region is adjusted to an arbitrary value in accordance with the thickness of the sealing insulator 71. For example, the cross-sectional area of the measurement region may be adjusted within a range of not less than 1 μm square to not more than 100 μm square (=not less than 25 μm² and not more than 10000 μm²). For example, the cross-sectional area of a measurement region may be adjusted in one of ranges of not less than 1 μm square and not more than 5 μm square, not less than 5 μm square and not more than 10 μm square, not less than 10 μm square and not more than 20 μm square, not less than 20 μm square and not more than 30 μm square, not less than 30 μm square and not more than 40 μm square, not less than 40 μm square and not more than 50 μm square, not less than 40 μm square and not more than 50 μm square, not less than 50 μm square and not more than 60 μm square, not less than 60 μm square and not more than 70 μm square, not less than 70 μm square and not more than 80 μm square, not less than 80 μm square and not more than 90 μm square, and not less than 90 μm square and not more than 100 μm square.

For example, when a measurement region of 10 μm square (=100 μm²) is extracted, the total cross-sectional area of the plurality of fillers 75 is not less than 60 μm² and not more than 95 μm². The ratio of the total cross-sectional area of the plurality of fillers 75 calculated in this manner may be converted into a ratio per 1 mm², a ratio per 100 μm², a ratio per 10 μm², and the like.

As a matter of course, the ratio of the total cross-sectional area of the plurality of fillers 75 may be calculated from an average of the ratios of a plurality of total cross-sectional areas obtained from a plurality of measurement regions. On a region other than a region on which the plurality of fillers 75 are exposed in a measurement region, the matrix resin 74 and the plurality of flexible particles 76 are exposed.

The plurality of flexible particles 76 are added into the matrix resin 74. The plurality of flexible particles 76 may include at least one of a silicone-based flexible particles 76, an acrylic-based flexible particles 76 and a butadiene-based flexible particles 76. The sealing insulator 71 preferably includes the silicone-based flexible particles 76. The plurality of flexible particles 76 preferably have an average particle size less than the average particle size of the plurality of fillers 75. The average particle size of the plurality of flexible particles 76 is preferably not less than 1 nm and not more than 1 μm. A maximum particle size of the plurality of flexible particles 76 is preferably not more than 1 μm.

The plurality of flexible particles 76 are added into the matrix resin 74 such that a ratio of a total cross-sectional area with respect to a unit cross-sectional area is to be not less than 0.1% and not more than 10%. In other words, the plurality of flexible particles 76 are added into the matrix resin 74 with a content of a range of not less than 0.1 wt % and not more than 10 wt %. The average particle size and the content of the plurality of flexible particles 76 are to be adjusted in accordance with an elastic modulus to be imparted to the sealing insulator 71 at a time of manufacturing and/or after manufacturing. For example, according to the plurality of flexible particles 76 having the average particle size of a submicron order (=not more than 1 μm), it makes it possible to contribute to a low elastic modulus and a low curing shrinkage of the sealing insulator 71.

The semiconductor device 1A includes a drain electrode 77 (second main surface electrode) that covers the second main surface 4. The drain electrode 77 is electrically connected to the second main surface 4. The drain electrode 77 forms an ohmic contact with the second semiconductor region 7 that is exposed from the second main surface 4. The drain electrode 77 may cover a whole region of the second main surface 4 such as to be continuous with the peripheral edge of the chip 2 (the first to fourth side surfaces 5A to 5D).

The drain electrode 77 may cover the second main surface 4 at an interval from the peripheral edge of the chip 2. The drain electrode 77 is configured such that a drain source voltage of not less than 500 V and not more than 3000 V is to be applied between the source terminal electrode 60 and the drain electrode 77. That is, the chip 2 is formed such that the voltage of not less than 500 V and not more than 3000 V is to be applied between the first main surface 3 and the second main surface 4.

As described above, the semiconductor device 1A includes the chip 2, the gate electrode 30 (the source electrode 32: main surface electrode), the gate terminal electrode 50 (the source terminal electrode 60) and the sealing insulator 71. The chip 2 has the first main surface 3. The gate electrode 30 (the source electrode 32) is arranged on the first main surface 3. The gate terminal electrode 50 (the source terminal electrode 60) is arranged on the gate electrode 30 (the source electrode 32).

The sealing insulator 71 covers the periphery of the gate terminal electrode 50 (the source terminal electrode 60) on the first main surface 3 such as to expose the gate terminal electrode 50 (the source terminal electrode 60). The sealing insulator 71 includes the matrix resin 74 and the plurality of fillers 75. The plurality of fillers 75 are added into the matrix resin 74 such that the ratio of the total cross-sectional area with respect to the unit cross-sectional area is higher than the ratio of the cross-sectional area of the matrix resin 74 with respect to the unit cross-sectional area.

This structure can improve the mechanical strength of the sealing insulator 71 and suppress a deformation of the chip 2 caused by the stress of the sealing insulator 71 and fluctuations in electrical characteristics. In addition, since the stress of the sealing insulator 71 can be suppressed, the relatively thick sealing insulator 71 can be formed. That is, it is possible to protect the object to be sealed from the first main surface 3 side while suppressing a deformation of the chip 2 caused by the stress of the sealing insulator 71 and fluctuations in electrical characteristics.

Also, according to this structure, an object to be sealed can be protected from an external force and a humidity (moisture) by the sealing insulator 71. That is, the object to be sealed can be protected from a damage (including peeling) due to the external force and deterioration (including corrosion) due to the humidity. It is therefore possible to suppress shape defects and fluctuations in electrical characteristics. As a result, it is possible to provide the semiconductor device 1A capable of improving reliability.

The plurality of fillers 75 are preferably added into the matrix resin 74 such that the ratio of the total cross-sectional area with respect to the unit cross-sectional area is not less than 60%. This structure can properly improve the mechanical strength of the sealing insulator 71. The total cross-sectional area is preferably not more than 95%. The plurality of fillers 75 may be composed of one of or both of spherical objects and indeterminate objects. The plurality of fillers 75 are preferably composed of spherical objects. The sealing insulator 71 preferably include the plurality of fillers 75 having different particle sizes.

The semiconductor device 1A preferably includes the upper insulating film 38 that partially covers the gate electrode 30 (the source electrode 32). According to this structure, an object to be covered can be protected from the external force and the humidity with the upper insulating film 38. That is, according to this structure, the object to be sealed can be protected by both of the upper insulating film 38 and the sealing insulator 71.

In such a structure, the sealing insulator 71 preferably has the portion directly covering the upper insulating film 38. The sealing insulator 71 preferably has the portion covering the gate electrode 30 (the source electrode 32) across the upper insulating film 38 interposed therebetween. The gate terminal electrode 50 (the source terminal electrode 60) preferably has the portion that directly covers the upper insulating film 38. The upper insulating film 38 preferably includes any one of or both of the inorganic insulating film 42 and the organic insulating film 43. The organic insulating film 43 preferably consists of the photosensitive resin film.

The upper insulating film 38 is preferably thicker than the gate electrode 30 (the source electrode 32). The upper insulating film 38 is preferably thinner than the chip 2. The sealing insulator 71 is preferably thicker than the gate electrode 30 (the source electrode 32). The sealing insulator 71 is preferably thicker than the upper insulating film 38. The sealing insulator 71 is particularly preferably thicker than the chip 2.

The sealing insulator 71 preferably exposes the gate terminal surface 51 (the source terminal surface 61) of the gate terminal electrode 50 (the source terminal electrode 60) and preferably covers the gate terminal side wall 52 (the source terminal side wall 62). That is, the sealing insulator 71 preferably protects the gate terminal electrode 50 (the source terminal electrode 60) from the gate terminal side wall 52 (the source terminal side wall 62).

In this case, the sealing insulator 71 preferably has the insulating main surface 72 that forms the single flat surface with the gate terminal surface 51 (the source terminal surface 61). The sealing insulator 71 preferably has the insulating side wall 73 that forms the single flat surface with the first to fourth side surfaces 5A to 5D (side surface) of the chip 2. According to this structure, the object to be sealed that is positioned on the first main surface 3 side can be appropriately protected with the sealing insulator 71.

Those above structures are effective when the gate terminal electrode 50 (the source terminal electrode 60) having a relatively large planar area and/or a relatively large thickness is applied to the chip 2 having a relatively large planar area and/or a relatively small thickness. The gate terminal electrode 50 (the source terminal electrode 60) having the relatively large planar area and/or the relatively large thickness is also effective in absorbing a heat generated on the chip 2 side and dissipating the heat to the outside.

For example, the gate terminal electrode 50 (the source terminal electrode 60) is preferably thicker than the gate electrode 30 (the source electrode 32). The gate terminal electrode 50 (the source terminal electrode 60) is preferably thicker than the upper insulating film 38. The gate terminal electrode 50 (the source terminal electrode 60) is particularly preferably thicker than the chip 2. For example, the gate terminal electrode 50 may cover the region of not more than 25% of the first main surface 3 in plan view, and the source terminal electrode 60 may cover the region of not less than 50% of the first main surface 3 in plan view.

For example, the chip 2 may have the first main surface 3 having the area of not less than 1 mm square in plan view. The chip 2 may have the thickness of not more than 100 μm in cross sectional view. The chip 2 preferably has the thickness of not more than 50 μm in cross sectional view. The chip 2 may have the laminated structure that includes the semiconductor substrate and the epitaxial layer. In this case, the epitaxial layer is preferably thicker than the semiconductor substrate.

In those above structures, the chip 2 preferably includes the monocrystal of the wide bandgap semiconductor. The monocrystal of the wide bandgap semiconductor is effective in improving electrical characteristics. Also, according to the monocrystal of the wide bandgap semiconductor, it is possible to achieve a thinning of the chip 2 and an increasing of the planar area of the chip 2 while suppressing a deformation of the chip 2 with a relatively high hardness. The thinning of the chip 2 and the increasing of the planar area of the chip 2 are also effective in improving the electrical characteristics.

The structure having the sealing insulator 71 is also effective in a structure that includes the drain electrode 77 covering the second main surface 4 of the chip 2. The drain electrode 77 forms a potential difference (for example, not less than 500 V and not more than 3000 V) with the source electrode 32 via the chip 2. In particular, in a case in which the chip 2 is relatively thin, a risk of a discharge phenomenon between the peripheral edge of the first main surface 3 and the source electrode 32 increases, since a distance between the source electrode 32 and the drain electrode 77 is shortened. In this point, according to the structure having the sealing insulator 71, an insulation property between the peripheral edge of the first main surface 3 and the source electrode 32 can be improved, and therefore the discharge phenomenon can be suppressed.

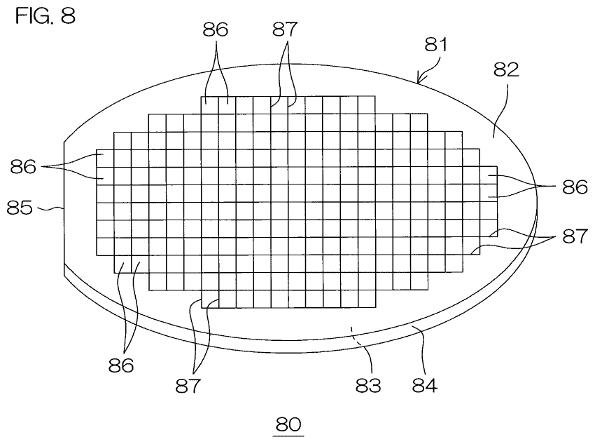

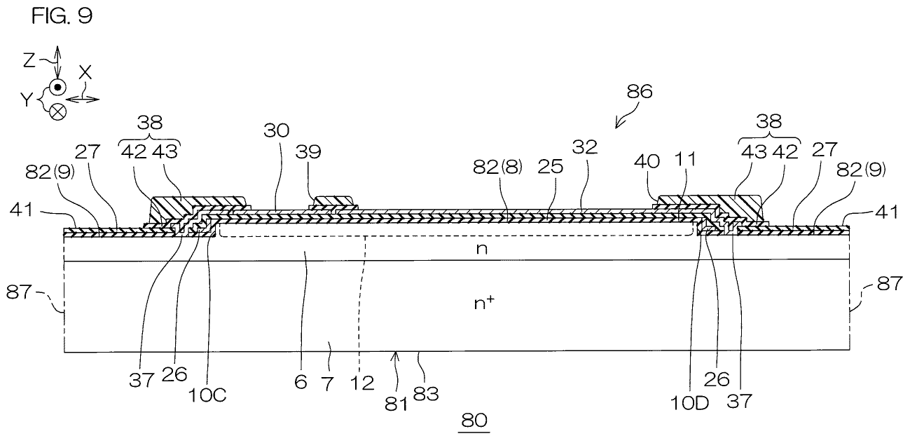

FIG. 8 is a perspective view showing a wafer structure 80 that is to be used at a time of manufacturing of the semiconductor device 1A shown in FIG. 1. FIG. 9 is a cross sectional view showing a device region 86 shown in FIG. 8. With reference to FIG. 8 and FIG. 9, the wafer structure 80 includes a wafer 81 formed in a disc shape. The wafer 81 is to be a base of the chip 2. The wafer 81 has a first wafer main surface 82 on one side, a second wafer main surface 83 on the other side, and a wafer side surface 84 connecting the first wafer main surface 82 and the second wafer main surface 83.

The wafer 81 has a mark 85 indicating a crystal orientation of the SiC monocrystal on the wafer side surface 84. The mark 85 includes an orientation flat cut out in a straight line in plan view, in this embodiment. The orientation flat extends in the second direction Y, in this embodiment. The orientation flat does not necessarily have to extend in the second direction Y and may extend in the first direction X.

As a matter of course, the mark 85 may include a first orientation flat extending in the first direction X and a second orientation flat extending in the second direction Y. Also, the mark 85 may have an orientation notch, instead of the orientation flat, cut out toward a central portion of the wafer 81. The orientation notch may be a notched portion cut into a polygonal shape such as a triangle shape and a quadrangle shape in plan view.

The wafer 81 may have a diameter of not less than 50 mm and not more than 300 mm (that is, not less than 2 inch and not more than 12 inch). The diameter of the wafer structure 80 is defined by a length of a chord passing through a center of the wafer structure 80 outside the mark 85. The wafer structure 80 may have a thickness of not less than 100 μm and not more than 1100 μm.

The wafer structure 80 includes the first semiconductor region 6 formed in a region on the first wafer main surface 82 side and the second semiconductor region 7 formed in a region on the second wafer main surface 83 side, inside the wafer 81. The first semiconductor region 6 is formed by an epitaxial layer, and the second semiconductor region 7 formed by a semiconductor substrate. That is, the first semiconductor region 6 is formed by an epitaxial growth of a semiconductor monocrystal from the second semiconductor region 7 by an epitaxial growth method. The second semiconductor region 7 preferably has a thickness exceeding a thickness of the first semiconductor region 6.

The wafer structure 80 includes a plurality of device regions 86 and a plurality of scheduled cutting lines 87 that are provided in the first wafer main surface 82. The plurality of device regions 86 are regions each corresponding to the semiconductor device 1A. The plurality of device regions 86 are each set in a quadrangle shape in plan view. The plurality of device regions 86 are arrayed in a matrix pattern along the first direction X and the second direction Y in plan view, in this embodiment.

The plurality of scheduled cutting lines 87 are lines (regions extending in band shapes) that define positions to be the first to fourth side surfaces 5A to 5D of the chip 2. The plurality of scheduled cutting lines 87 are set in a lattice pattern extending along the first direction X and the second direction Y such as to define the plurality of device regions 86. For example, the plurality of scheduled cutting lines 87 may be demarcated by alignment marks and the like that are provided inside and/or outside the wafer 81.

The wafer structure 80 includes the mesa portion 11, the MISFET structure 12, the outer contact region 19, the outer well region 20, the field regions 21, the main surface insulating film 25, the side wall structure 26, the interlayer insulating film 27, the gate electrode 30, the source electrode 32, the plurality of gate wirings 36A, 36B, the source wiring 37 and the upper insulating film 38 formed in each of the device regions 86, in this embodiment.

The wafer structure 80 includes the dicing street 41 demarcated in regions among the plurality of upper insulating films 38. That is, the dicing street 41 straddles the plurality of device regions 86 across the plurality of scheduled cutting lines 87 such as to expose the plurality of scheduled cutting lines 87. The dicing street 41 is formed in a lattice pattern extending along the plurality of scheduled cutting lines 87. The dicing street 41 exposes the interlayer insulating film 27, in this embodiment. As a matter of course, in a case in which the interlayer insulating film 27 exposing the first wafer main surface 82, the dicing street 41 may expose the first wafer main surface 82.

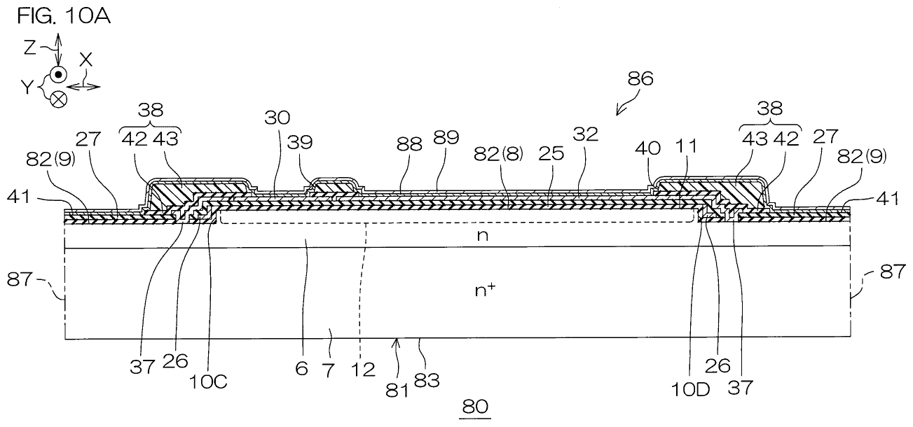

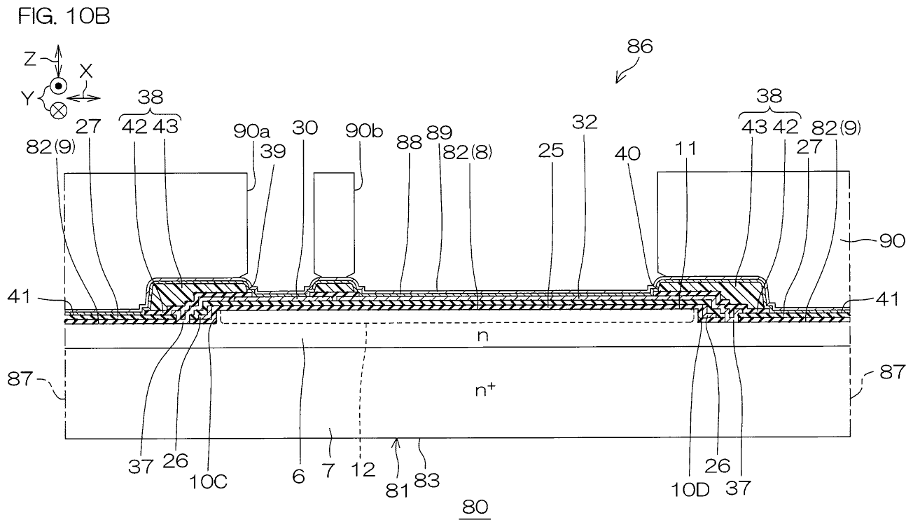

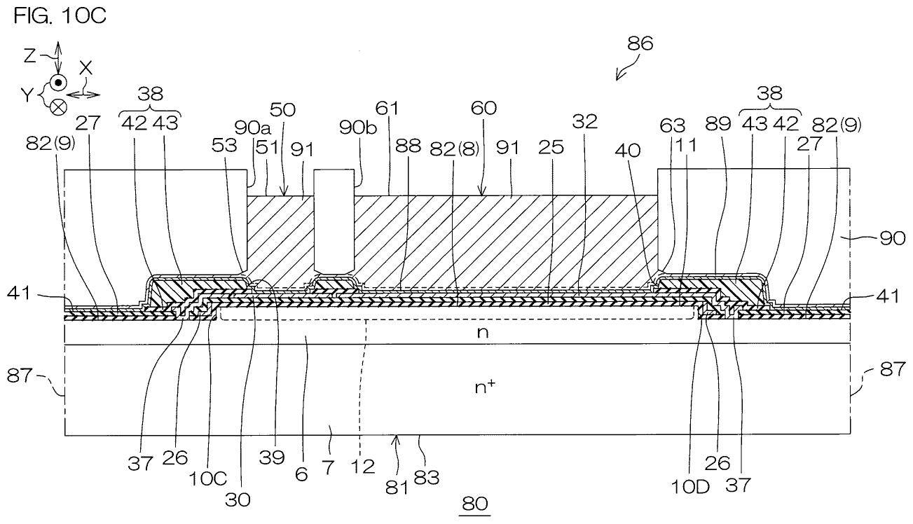

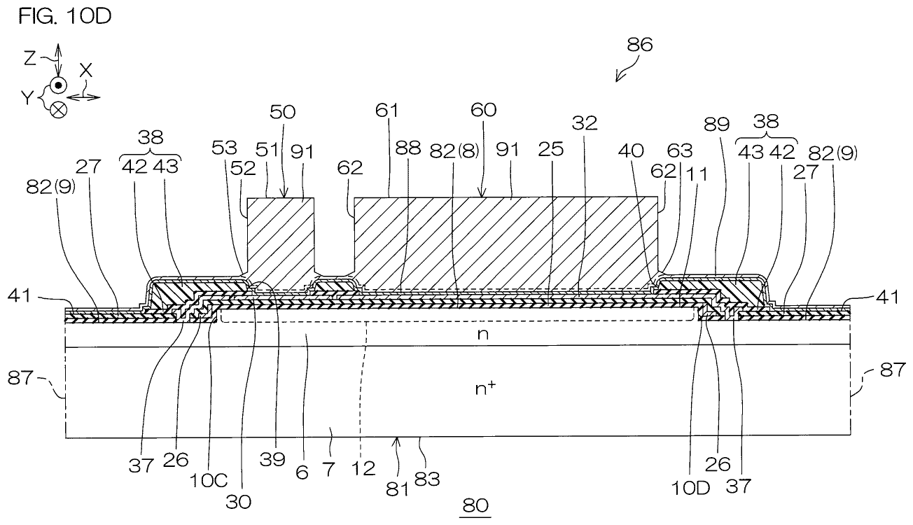

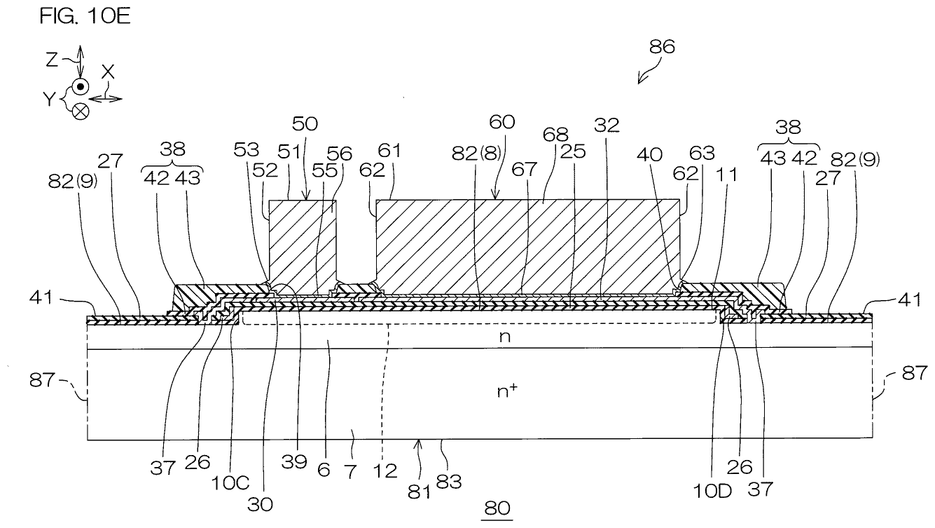

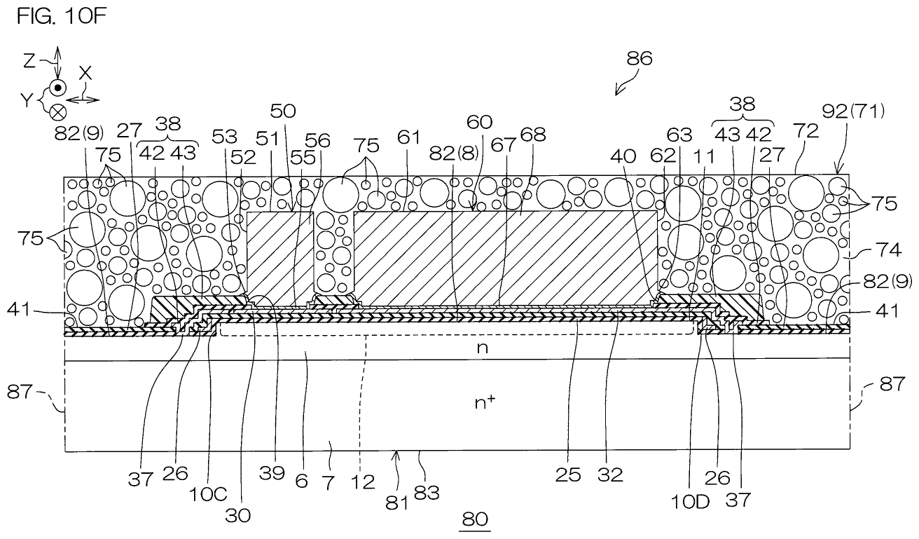

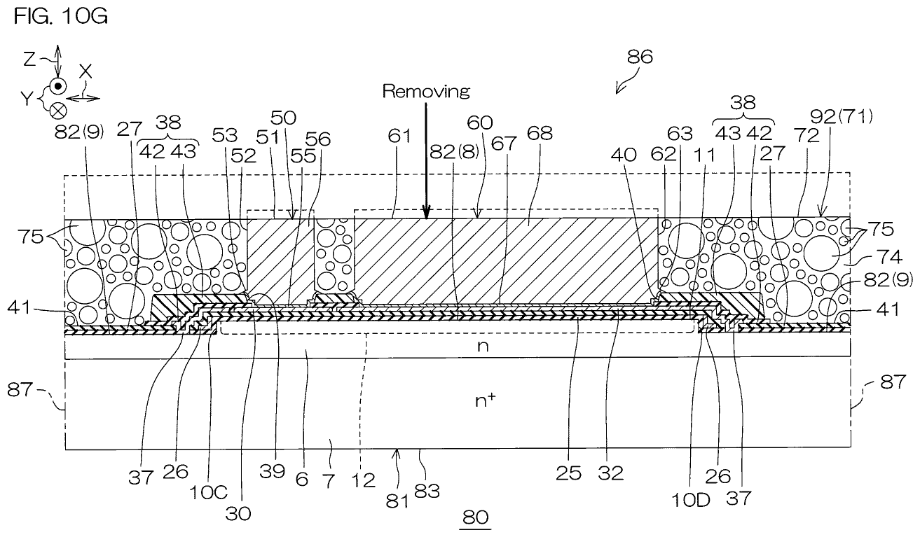

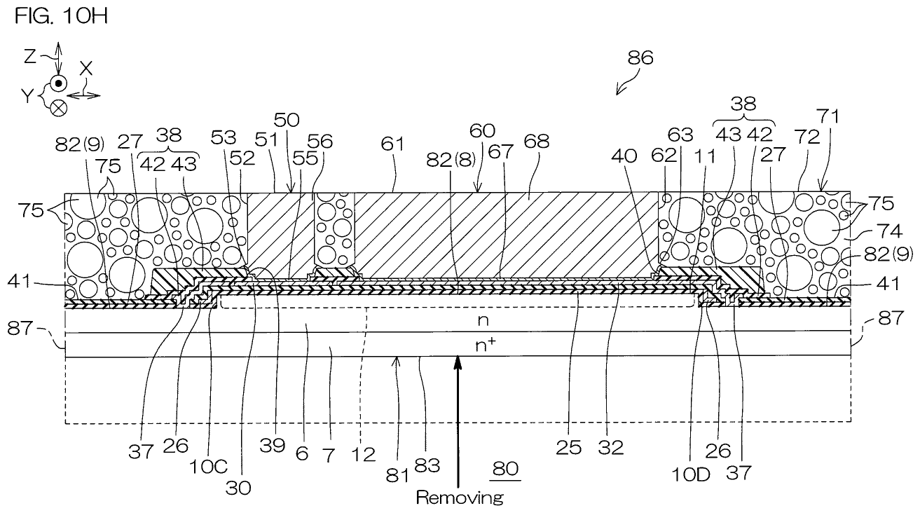

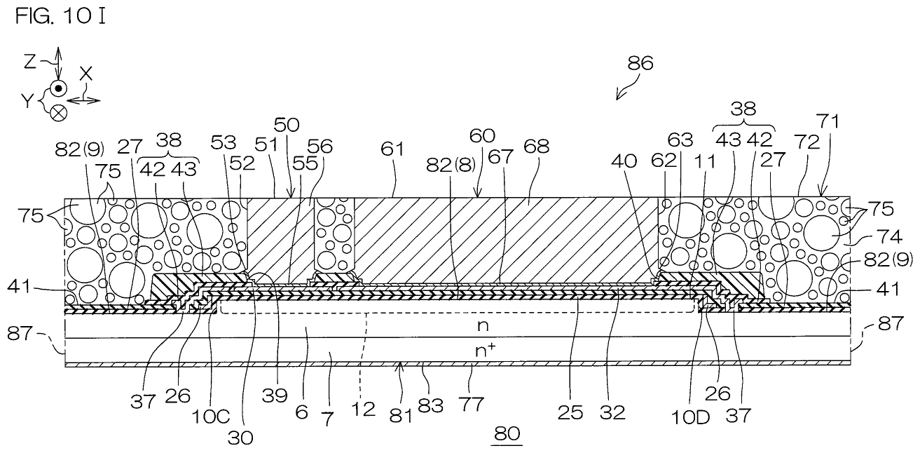

FIG. 10A to FIG. 10I are cross sectional views showing a manufacturing method example for the semiconductor device 1A shown in FIG. 1. Descriptions of the specific features of each structure that are formed in each process shown in FIG. 10A to FIG. 10I shall be omitted or simplified, since those have been as described above.

With reference to FIG. 10A, the wafer structure 80 is prepared (see FIG. 8 and FIG. 9). Next, a first base conductor film 88 to be a base of the first gate conductor film 55 and the first source conductor film 67 is formed on the wafer structure 80s. The first base conductor film 88 is formed in a film shape along the interlayer insulating film 27, the gate electrode 30, the source electrode 32, the plurality of gate wirings 36A, 36B, the source wiring 37 and the upper insulating film 38. The first base conductor film 88 includes a Ti-based metal film. The first base conductor film 88 may be formed by a sputtering method and/or a vapor deposition method.

Next, a second base conductor film 89 to be a base of the second gate conductor film 56 and the second source conductor film 68 is formed on the first base conductor film 88. The second base conductor film 89 covers the interlayer insulating film 27, the gate electrode 30, the source electrode 32, the plurality of gate wirings 36A, 36B, the source wiring 37 and the upper insulating film 38 in a film shape with the first base conductor film 88 interposed therebetween. The second base conductor film 89 includes a Cu-based metal film. The second base conductor film 89 may be formed by a sputtering method and/or a vapor deposition method.

Next, with reference to FIG. 10B, a resist mask 90 having a predetermined pattern is formed on the second base conductor film 89. The resist mask 90 includes a first opening 90a exposing the gate electrode 30 and a second opening 90b exposing the source electrode 32. The first opening 90a exposes a region in which the gate terminal electrode 50 is to be formed at a region on the gate electrode 30. The second opening 90b exposes a region in which the source terminal electrode 60 is to be formed at a region on the source electrode 32.

This step includes a step of reducing an adhesion of the resist mask 90 with respect to the second base conductor film 89. The adhesion of the resist mask 90 is to be adjusted by adjusting exposure conditions and/or bake conditions (baking temperature, time, etc.) after exposure for the resist mask 90. Through this step, a growth starting point of the first protrusion portion 53 is formed at a lower end portion of the first opening 90a, and a growth starting point of the second protrusion portion 63 is formed at a lower end portion of the second opening 90b.

Next, with reference to FIG. 10C, a third base conductor film 91 to be a base of the second gate conductor film 56 and the second source conductor film 68 is formed on the second base conductor film 89. The third base conductor film 91 is formed by depositing a conductor (in this embodiment, Cu-based metal) in the first opening 90a and the second opening 90b by a plating method (for example, electroplating method), in this embodiment. The third base conductor film 91 integrates with the second base conductor film 89 inside the first opening 90a and the second opening 90b. Through this step, the gate terminal electrode 50 that covers the gate electrode 30 is formed. Also, the source terminal electrode 60 that covers the source electrode 32 is formed.

This step includes a step of entering a plating solution between the second base conductor film 89 and the resist mask 90 at the lower end portion of the first opening 90a. Also, this step includes a step of entering the plating solution between the second base conductor film 89 and the resist mask 90 at the lower end portion of the second opening 90b. Through this step, a part of the third base conductor film 91 (the gate terminal electrode 50) is grown into a protrusion shape at the lower end portion of the first opening 90a and the first protrusion portion 53 is thereby formed. Also, a part of the third base conductor film 91 (the source terminal electrode 60) is grown into a protrusion shape at the lower end portion of the second opening 90b and the second protrusion portion 63 is thereby formed.

Next, with reference to FIG. 10D, the resist mask 90 is removed. Through this step, the gate terminal electrode 50 and the source terminal electrode 60 are exposed outside.

Next, with reference to FIG. 10E, a portion of the second base conductor film 89 that is exposed from the gate terminal electrode 50 and the source terminal electrode 60. An unnecessary portion of the second base conductor film 89 may be removed by an etching method. The etching method may be a wet etching method and/or a dry etching method. Next, a portion of the first base conductor film 88 that is exposed from the gate terminal electrode 50 and the source terminal electrode 60 is removed. An unnecessary portion of the first base conductor film 88 may be removed by an etching method. The etching method may be a wet etching method and/or a dry etching method.

Next, with reference to FIG. 10F, a sealant 92 is supplied on the first wafer main surface 82 such as to cover the gate terminal electrode 50 and the source terminal electrode 60. The sealant 92 is to be a base of the sealing insulator 71. The sealant 92 covers a periphery of the gate terminal electrode 50 and a periphery of the source terminal electrode 60, and covers a whole region of the upper insulating film 38, a whole region of the gate terminal electrode 50 and a whole region of the source terminal electrode 60.

In this embodiment, the sealant 92 includes the matrix resin 74, the plurality of fillers 75, and the plurality of flexible particles 76 (flexible agent). The plurality of fillers 75 are added into the matrix resin 74 such that a ratio of a total cross-sectional area with respect to a unit cross-sectional area is higher than a ratio of a cross-sectional area of the matrix resin 74 with respect to the unit cross-sectional area. That is, the viscosity of the sealant 92 is increased by the plurality of fillers 75.

The plurality of fillers 75 are preferably added into the matrix resin 74 such that a ratio of a total cross-sectional area with respect to a unit cross-sectional area is not less than 60%. After the supply step of the sealant 92, the sealant 92 is thermoset by heating and the sealing insulator 71 is formed. The sealing insulator 71 has the insulating main surface 72 covering a whole region of the gate terminal electrode 50 and a whole region of the source terminal electrode 60.

Next, with reference to FIG. 10G, the sealing insulator 71 is partially removed. The sealing insulator 71 is ground from the insulating main surface 72 side by a grinding method, in this embodiment. The grinding method may be a mechanical polishing method and/or a chemical mechanical polishing method. The insulating main surface 72 is ground until the gate terminal electrode 50 and the source terminal electrode 60 are exposed. This step includes a grinding step of the gate terminal electrode 50 and the source terminal electrode 60. Through this step, the insulating main surface 72 that forms the single grinding surface with the gate terminal electrode 50 (the gate terminal surface 51) and the source terminal electrode 60 (the source terminal surface 61) is formed.

Next, with reference to FIG. 10H, the wafer 81 is partially removed from the second wafer main surface 83 side, and the wafer 81 is thinned until a desired thickness is obtained. The thinning step of the wafer 81 is performed by an etching method and/or a grinding method. The etching method may be a wet etching method and/or a dry etching method. The grinding method may be a mechanical polishing method and/or a chemical mechanical polishing method.

This step includes a step of thinning the wafer 81 by using the sealing insulator 71 as a supporting member that supports the wafer 81. This allows for proper handling of the wafer 81. Also, it is possible to suppress a deformation (warpage due to thinning) of the wafer 81 with the sealing insulator 71, and therefore the wafer 81 can be appropriately thinned.

As one example, in a case in which the thickness of the wafer 81 is less than the thickness of the sealing insulator 71, the wafer 81 is further thinned. As the other example, in a case in which the thickness of the wafer 81 is not less than the thickness of the sealing insulator 71, the wafer 81 is thinned until the thickness of the wafer 81 becomes less than the thickness of the sealing insulator 71. In those cases, the wafer 81 is preferably thinned until a thickness of the second semiconductor region 7 (the semiconductor substrate) becomes less than a thickness of the first semiconductor region 6 (the epitaxial layer).

As a matter of course, the thickness of the second semiconductor region 7 (the semiconductor substrate) may be not less than the thickness of the first semiconductor region 6 (the epitaxial layer). Also, the wafer 81 may be thinned until the first semiconductor region 6 is exposed from the second wafer main surface 83. That is, all of the second semiconductor region 7 may be removed.

Next, with reference to FIG. 10I, the drain electrode 77 covering the second wafer main surface 83 is formed. The drain electrode 77 may be formed by a sputtering method and/or a vapor deposition method. The wafer structure 80 and the sealing insulator 71 are cut along the scheduled cutting lines 87 thereafter. The wafer structure 80 and the sealing insulator 71 may be cut by a dicing blade (not shown). Through the steps including the above, the plurality of semiconductor devices 1A are manufactured from the single wafer structure 80.

As described above, the manufacturing method for the semiconductor device 1A includes the preparation step of the wafer structure 80, the forming step of the gate terminal electrode 50 (the source terminal electrode 60), and the forming step of the sealing insulator 71. The wafer structure 80 includes the wafer 81 and the gate electrode 30 (the source electrode 32: main surface electrode). The wafer 81 has the first wafer main surface 82. The gate electrode 30 (the source electrode 32) is arranged on the first wafer main surface 82. In the forming step of the gate terminal electrode 50 (the source terminal electrode 60), the gate terminal electrode 50 (the source terminal electrode 60) is formed on the gate electrode 30 (the source electrode 32).

In the forming step of the sealing insulator 71, the gate terminal electrode 50 (the source terminal electrode 60) covering the periphery of the gate terminal electrode 50 (the source terminal electrode 60) is formed on the first wafer main surface 82 such as to expose a part of the gate terminal electrode 50 (the source terminal electrode 60). The sealing insulator 71 includes the matrix resin 74 and the plurality of fillers 75. The plurality of fillers 75 are added into the matrix resin 74 such that the ratio of the total cross-sectional area with respect to the unit cross-sectional area is higher than the ratio of the cross-sectional area of the matrix resin 74 with respect to the unit cross-sectional area.

According to this manufacturing method, it is possible to improve the mechanical strength of the sealing insulator 71 and suppress a deformation of the wafer 81 caused by the stress of the sealing insulator 71 and fluctuations in electrical characteristics. In addition, since the stress of the sealing insulator 71 can be suppressed, the relatively thick sealing insulator 71 can be formed. That is, it is possible to protect the object to be sealed from the first main surface 3 side while suppressing a deformation of the wafer 81 caused by the stress of the sealing insulator 71 and fluctuations in electrical characteristics.

Also, according to this manufacturing method, an object to be sealed can be protected from external force and humidity (moisture) by the sealing insulator 71. That is, the object to be sealed can be protected from a damage (including peeling) due to the external force and deterioration (including corrosion) due to the humidity. It is therefore possible to suppress shape defects and fluctuations in electrical characteristics. As a result, it is possible to manufacture the semiconductor device 1A capable of improving the reliability.

The plurality of fillers 75 are preferably added into the matrix resin 74 such that the ratio of the total cross-sectional area with respect to the unit cross-sectional area is not less than 60%. This structure can properly improve the mechanical strength of the sealing insulator 71. The total cross-sectional area is particularly preferably not less than 80%. The total cross-sectional area is preferably not more than 95%. The plurality of fillers 75 may be composed of one of or both of spherical objects and indeterminate objects. The plurality of fillers 75 are preferably composed of spherical objects. The sealing insulator 71 preferably include the plurality of fillers 75 having different particle sizes.

The forming step of the sealing insulator 71 preferably includes the supply step of the sealant 92 and the thermosetting step of the sealant 92. In the supply step of the sealant 92, the sealant 92 including the matrix resin 74 consisting of the thermosetting resin and the plurality of fillers 75 is supplied onto the first wafer main surface 82. In the thermosetting step of the sealant 92, the sealing insulator 71 is formed by thermosetting the sealant 92.

In this case, the sealant 92 is preferably supplied onto the first wafer main surface 82 such as to cover the whole region of the gate terminal electrode 50 (the source terminal electrode 60). In this case, the forming step of the sealing insulator 71 preferably includes the step of partially removing the sealing insulator 71 until the gate terminal electrode 50 (the source terminal electrode 60) is partially exposed after the thermosetting step of the sealant 92.

The forming step of the gate terminal electrode 50 (the source terminal electrode 60) preferably includes the step of forming the gate terminal electrode 50 (the source terminal electrode 60) thicker than the gate electrode 30 (the source electrode 32). The forming step of the sealing insulator 71 preferably includes the step of forming the sealing insulator 71 thicker than the gate electrode 30 (the source electrode 32).

The manufacturing method for the semiconductor device 1A preferably includes the step of thinning the wafer 81 after the forming step of the sealing insulator 71. According to this manufacturing method, since stress from the sealing insulator 71 with respect to the wafer 81 can be reduced, the wafer 81 can be properly thinned. In this case, the wafer 81 may be thinned by using the sealing insulator 71 as the support member.

The thinning step of the wafer 81 preferably includes the step of thinning the wafer 81 until the thickness becomes less than the thickness of the sealing insulator 71. The thinning step of the wafer 81 preferably includes the step of thinning the wafer 81 until it becomes thinner than the gate terminal electrode 50 (the source terminal electrode 60). The thinning step of the wafer 81 preferably includes the step of thinning the wafer 81 by the grinding method.

The wafer 81 preferably has the laminated structure including the substrate and the epitaxial layer and has the first wafer main surface 82 formed by the epitaxial layer. In this case, the thinning step of the wafer 81 may include the step of removing at least part of the substrate. For example, the thinning step of the wafer 81 may include the step of thinning the substrate until it becomes thinner than the epitaxial layer. The wafer 81 preferably includes the monocrystal of the wide bandgap semiconductor.

The forming step of the gate terminal electrode 50 (the source terminal electrode 60) preferably includes the step of forming the second base conductor film 89 (conductor film) covering the gate electrode 30 (the source electrode 32), the step of forming, on the second base conductor film 89, the resist mask 90 that exposes the portion of the second base conductor film 89 that covers the gate electrode 30 (the source electrode 32), the step of depositing the third base conductor film 91 (conductor) on the portion of the second base conductor film 89 that is exposed from the resist mask 90, and the step of removing the resist mask 90 after the deposition step of the third base conductor film 91.

The manufacturing method for the semiconductor device 1A preferably includes the step of forming the upper insulating film 38 that partially covers the gate electrode 30 (the source electrode 32) before the forming step of the gate terminal electrode 50 (the source terminal electrode 60). In this case, the supply step of the sealant 92 preferably includes the step of supplying the sealant 92 into an opening portion 95 such as to cover the gate terminal electrode 50 (the source terminal electrode 60) and the upper insulating film 38.

The forming step of the gate terminal electrode 50 (the source terminal electrode 60) preferably includes the step of forming the gate terminal electrode 50 (the source terminal electrode 60) having the portion directly covering the upper insulating film 38. The forming step of the upper insulating film 38 preferably includes the step of forming the upper insulating film 38 including at least one of the inorganic insulating film 42 and the organic insulating film 43.

In the preparation step of the wafer structure 80, it is preferable to prepare the wafer structure 80 including the wafer 81, the device region 86, the scheduled cutting lines 87, and the gate electrode 30 (the source electrode 32). The device region 86 is set in the wafer 81 (the first wafer main surface 82). The scheduled cutting lines 87 is set in the wafer 81 (the first wafer main surface 82) such as to define the device region 86. The gate electrode 30 (the source electrode 32) is arranged on the first wafer main surface 82 in the device region 86. In this case, the manufacturing method for the semiconductor device 1A preferably includes the step of cutting the wafer 81 and the sealing insulator 71 along the scheduled cutting lines 87 after the forming step of the sealing insulator 71 (specifically, after the removing step of the sealing insulator 71).

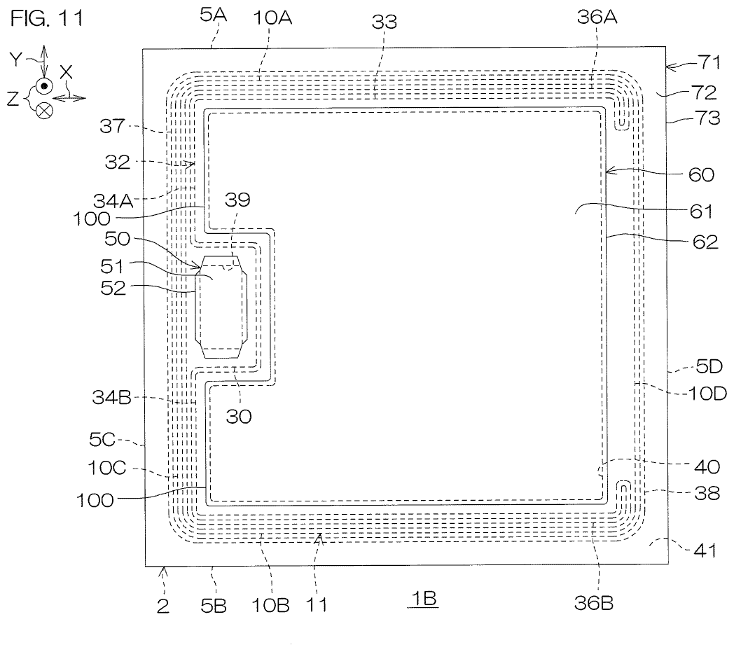

FIG. 11 is a plan view showing a semiconductor device 1B according to a second embodiment. With reference to FIG. 11, the semiconductor device 1B has a modified mode of the semiconductor device 1A. Specifically, the semiconductor device 1B includes the source terminal electrode 60 that has at least one (in this embodiment, a plurality of) drawer terminal portions 100. Specifically, the plurality of drawer terminal portions 100 are each drawn out onto the plurality of drawer electrode portions 34A, 34B of the source electrode 32 such as to oppose the gate terminal electrode 50 in the second direction Y. That is, the plurality of drawer terminal portions 100 sandwich the gate terminal electrode 50 from both sides of the second direction Y in plan view.

As described above, the same effects as those of the semiconductor device 1A are also achieved with the semiconductor device 1B. Also, the semiconductor device 1B is manufactured through the similar manufacturing method to the manufacturing method for the semiconductor device 1A. Therefore, the same effects as those of the manufacturing method for the semiconductor device 1A are also achieved with the manufacturing method for the semiconductor device 1B.

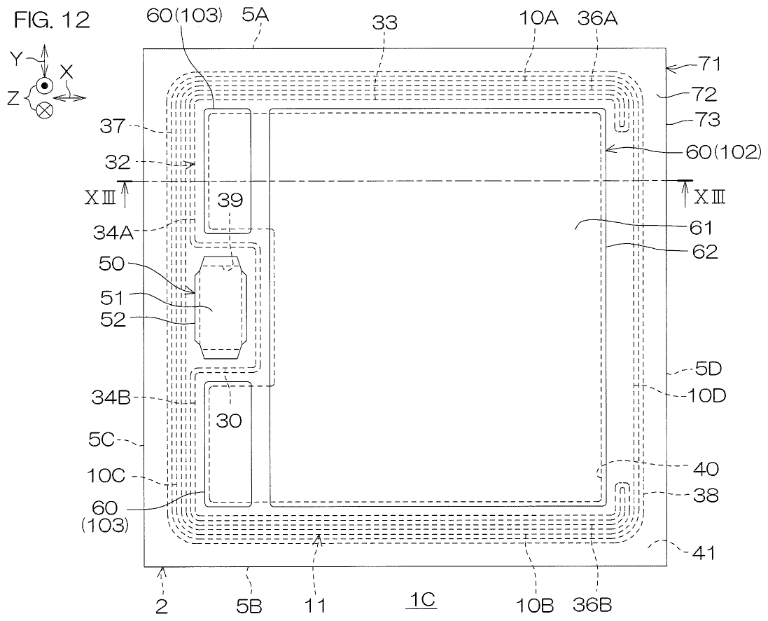

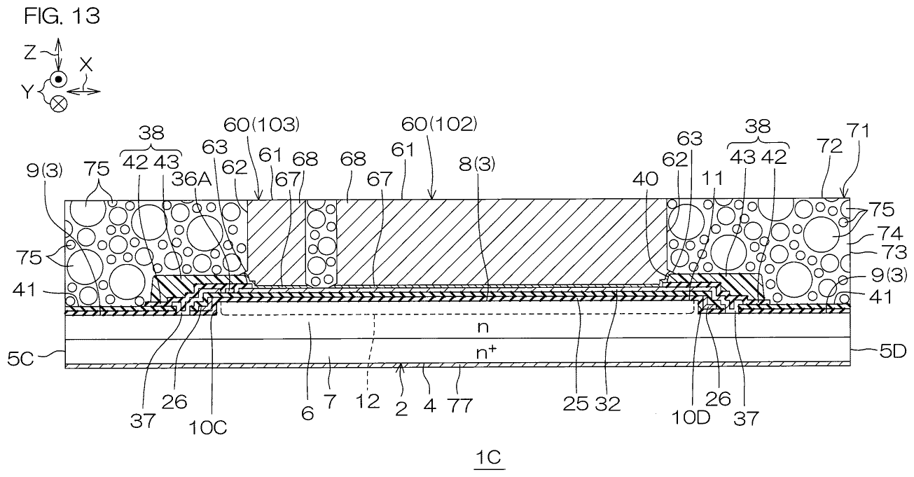

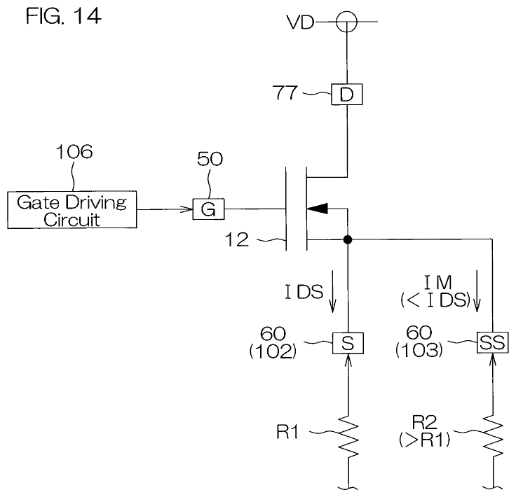

FIG. 12 is a plan view showing a semiconductor device 1C according to a third embodiment. FIG. 13 is a cross sectional view taken along XIII-XIII line shown in FIG. 12. FIG. 14 is a circuit diagram showing an electrical configuration of the semiconductor device 1C shown in FIG. 12. With reference to FIG. 12 to FIG. 14, the semiconductor device 1C has a modified mode of the semiconductor device 1A.

Specifically, the semiconductor device 1C includes the plurality of source terminal electrodes 60 that are arranged on the source electrode 32 at intervals from each other. The semiconductor device 1C includes at least one (in this embodiment, one) source terminal electrode 60 that is arranged on the body electrode portion 33 of the source electrode 32 and at least one (in this embodiment, a plurality of) source terminal electrodes 60 that are arranged on the plurality of drawer electrode portions 34A, 34B of the source electrode 32, in this embodiment.

The source terminal electrode 60 on the body electrode portion 33 side is formed as a main terminal electrode 102 that conducts a drain source current IDS, in this embodiment. The plurality of source terminal electrodes 60 on the plurality of drawer electrode portions 34A, 34B sides are each formed as a sense terminal electrode 103 that conducts a monitor current IM which monitors the drain source current IDS, in this embodiment. Each of the sense terminal electrodes 103 has an area less than an area of the main terminal electrode 102 in plan view.

One sense terminal electrode 103 is arranged on the first drawer electrode portion 34A and faces the gate terminal electrode 50 in the second direction Y in plan view. The other sense terminal electrode 103 is arranged on the second drawer electrode portion 34B and faces the gate terminal electrode 50 in the second direction Y in plan view. The plurality of sense terminal electrodes 103 therefore sandwich the gate terminal electrode 50 from both sides of the second direction Y in plan view.

With reference to FIG. 14, in the semiconductor device 1C, a gate driving circuit 106 is to be electrically connected to the gate terminal electrode 50, at least one first resistance R1 is to be electrically connected to the main terminal electrode 102, and at least one second resistance R2 is to be electrically connected to the plurality of sense terminal electrodes 103. The first resistance R1 is configured such as to conduct the drain source current IDS that is generated in the semiconductor device 1C. The second resistance R2 is configured such as to conduct the monitor current IM having a value less than that of the drain source current IDS.

The first resistance R1 may be a resistor or a conductive bonding member with a first resistance value. The second resistance R2 may be a resistor or a conductive bonding member with a second resistance value more than the first resistance value. The conductive bonding member may be a conductor plate or a conducting wire (for example, bonding wire). That is, at least one first bonding wire with the first resistance value may be connected to the main terminal electrode 102.

Also, at least one second bonding wire with the second resistance value more than the first resistance value may be connected to at least one of the sense terminal electrodes 103. The second bonding wire may have a line thickness less than a line thickness of the first bonding wire. In this case, a bonding area of the second bonding wire with respect to the sense terminal electrode 103 may be less than a bonding area of the first bonding wire with respect to the main terminal electrode 102.

As described above, the same effects as those of the semiconductor device 1A are also achieved with the semiconductor device 1C. In the manufacturing method for the semiconductor device 1C, the resist mask 90 having the plurality of second openings 90b that exposes regions in each of which the source terminal electrode 60 and the sense terminal electrode 103 are to be formed is formed in the manufacturing method for the semiconductor device 1A, and then the same steps as those of the manufacturing method for the semiconductor device 1A are performed. Therefore, the same effects as those of the manufacturing method for the semiconductor device 1A are also achieved with the manufacturing method for the semiconductor device 1C.

In this embodiment, an example in which the sense terminal electrodes 103 are formed on the drawer electrode portions 34A, 34B, but the arrangement locations of the sense terminal electrodes 103 are arbitrary. Therefore, the sense terminal electrode 103 may be arranged on the body electrode portion 33. In this embodiment, an example in which the sense terminal electrode 103 is applied to the semiconductor device 1A has been shown. As a matter of course, the sense terminal electrode 103 may be applied to the second embodiment.

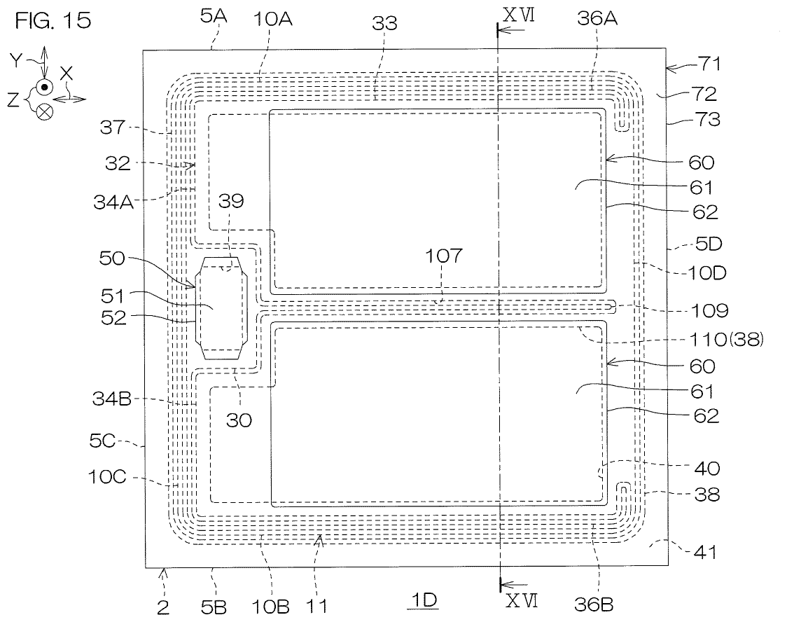

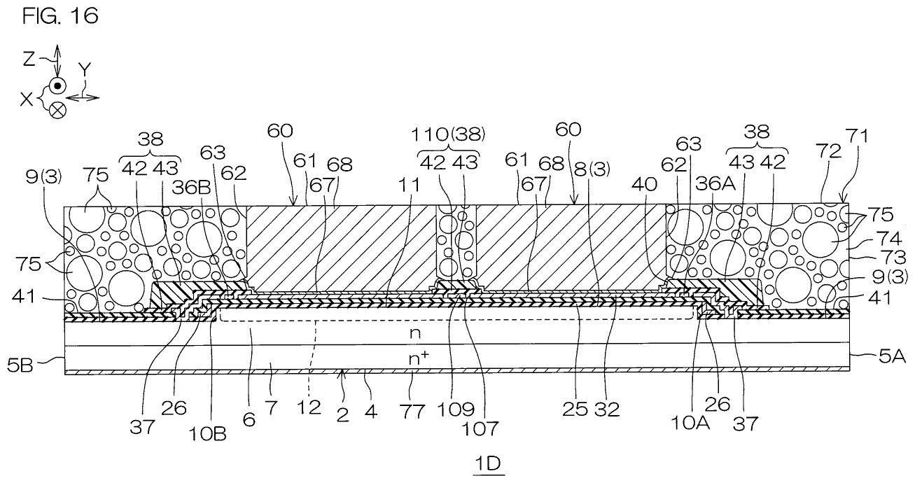

FIG. 15 is a plan view showing a semiconductor device 1D according to a fourth embodiment. FIG. 16 is a cross sectional view taken along XVI-XVI line shown in FIG. 15. With reference to FIG. 15 and FIG. 16, the semiconductor device 1D has a modified mode of the semiconductor device 1A. Specifically, the semiconductor device 1D includes a gap portion 107 that formed in the source electrode 32.

The gap portion 107 is formed in the body electrode portion 33 of the source electrode 32. The gap portion 107 penetrates the source electrode 32 to expose a part of the interlayer insulating film 27 in cross sectional view. The gap portion 107 extends in a band shape toward an inner portion of the source electrode 32 from a portion of a wall portion of the source electrode 32 that opposes the gate electrode 30 in the first direction X, in this embodiment.

The gap portion 107 is formed in a band shape extending in the first direction X, in this embodiment. The gap portion 107 crosses a central portion of the source electrode 32 in the first direction X in plan view, in this embodiment. The gap portion 107 has an end portion at a position at an interval inward (to the gate electrode 30 side) from a wall portion of the source electrode 32 on the fourth side surface 5D side in plan view. As a matter of course, the gap portion 107 may divide the source electrode 32 into the second direction Y.

The semiconductor device 1D includes a gate intermediate wiring 109 that is drawn out into the gap portion 107 from the gate electrode 30. The gate intermediate wiring 109 has a laminated structure that includes the first gate conductor film 55 and the second gate conductor film 56 as with the gate electrode 30 (the plurality of gate wiring 36A, 36B). The gate intermediate wiring 109 is formed at an interval from the source electrode 32 and extends in a band shape along the gap portion 107 in plan view.

The gate intermediate wiring 109 penetrates the interlayer insulating film 27 at an inner portion of the active surface 8 (the first main surface 3) and is electrically connected to the plurality of gate structures 15. The gate intermediate wiring 109 may be directly connected to the plurality of gate structures 15, or may be electrically connected to the plurality of gate structures 15 via a conductor film.

The upper insulating film 38 aforementioned includes the gap covering portion 110 that covers the gap portion 107 of the source electrode 32, in this embodiment. The gap covering portion 110 covers a whole region of the gate intermediate wiring 109 inside the gap portion 107. The gap covering portion 110 may be drawn out onto the source electrode 32 from inside the gap portion 107 such as to cover the peripheral edge portion of the source electrode 32.

The semiconductor device 1D includes the plurality of source terminal electrodes 60 that are arranged on the source electrode 32 at an interval from each other, in this embodiment. The plurality of source terminal electrodes 60 are each arranged on the source electrode 32 at an interval from the gap portion 107 and face each other in the second direction Y in plan view. The plurality of source terminal electrodes 60 are arranged such as to expose the gap covering portion 110, in this embodiment.

The plurality of source terminal electrodes 60 are each formed in a quadrangle shape (specifically, rectangular shape extending in the first direction X) in plan view, in this embodiment. The planar shapes of the plurality of source terminal electrodes 60 is arbitrary, and may each be formed in a polygonal shape other than the quadrangle shape, a circular shape, or an elliptical shape in plan view. The plurality of source terminal electrodes 60 may each include the second protrusion portion 63 that is formed on the gap covering portion 110 of the upper insulating film 38.

The sealing insulator 71 aforementioned covers the gap portion 107 at a region between the plurality of source terminal electrodes 60, in this embodiment. The sealing insulator 71 covers the gap covering portion 110 of the upper insulating film 38 at a region between the plurality of source terminal electrodes 60. That is, the sealing insulator 71 covers the gate intermediate wiring 109 with the upper insulating film 38 interposed therebetween.

An example in which the upper insulating film 38 has the gap covering portion 110 has been shown, in this embodiment. However, the presence or the absence of the gap covering portion 110 is arbitrary, and the upper insulating film 38 without the gap covering portion 110 may be formed. In this case, the plurality of source terminal electrodes 60 are formed on the source electrode 32 such as to expose the gate intermediate wiring 109. The sealing insulator 71 directly covers the gate intermediate wiring 109, and electrically isolates the gate intermediate wiring 109 from the source electrode 32. The sealing insulator 71 directly covers a part of the interlayer insulating film 27 that exposes at a region between the source electrode 32 and the gate intermediate wiring 109 inside the gap portion 107.

As described above, the same effects as those of the semiconductor device 1A are also achieved with the semiconductor device 1D. In the manufacturing method for the semiconductor device 1D, the wafer structure 80 in which structures corresponding to the semiconductor device 1D are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1D.

An example in which the gap portion 107, the gate intermediate wiring 109, the gap covering portion 110, etc., are applied to the semiconductor device 1A has been shown, in this embodiment. As a matter of course, the gap portion 107, the gate intermediate wiring 109, the gap covering portion 110, etc., may be applied to the second and third embodiments.

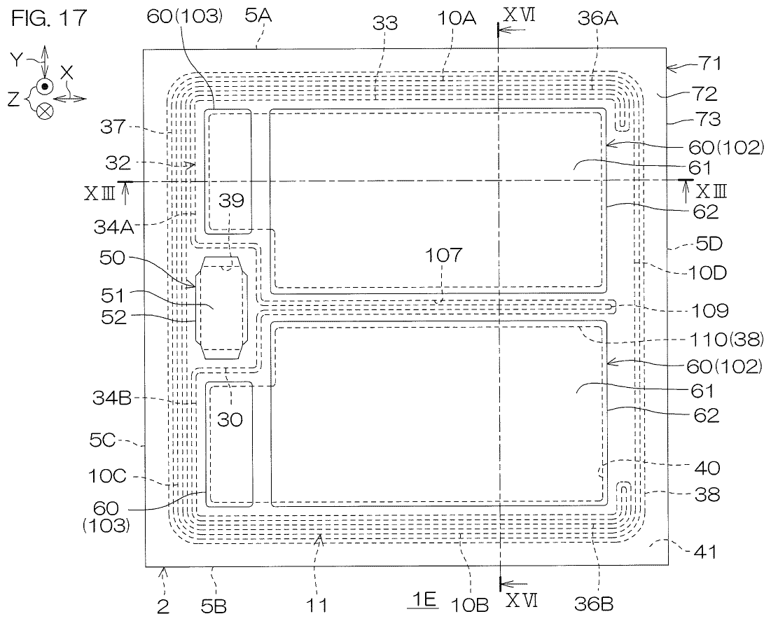

FIG. 17 is a plan view showing a semiconductor device 1E according to a fifth embodiment. With reference to FIG. 17, the semiconductor device 1E has a mode in which the features (structures having the gate intermediate wiring 109) of the semiconductor device 1D according to the fourth embodiment are combined to the features (structures having the sense terminal electrode 103) of the semiconductor device 1C according to the third embodiment. The same effects as those of the semiconductor device 1A are also achieved with the semiconductor device 1E having such a mode.

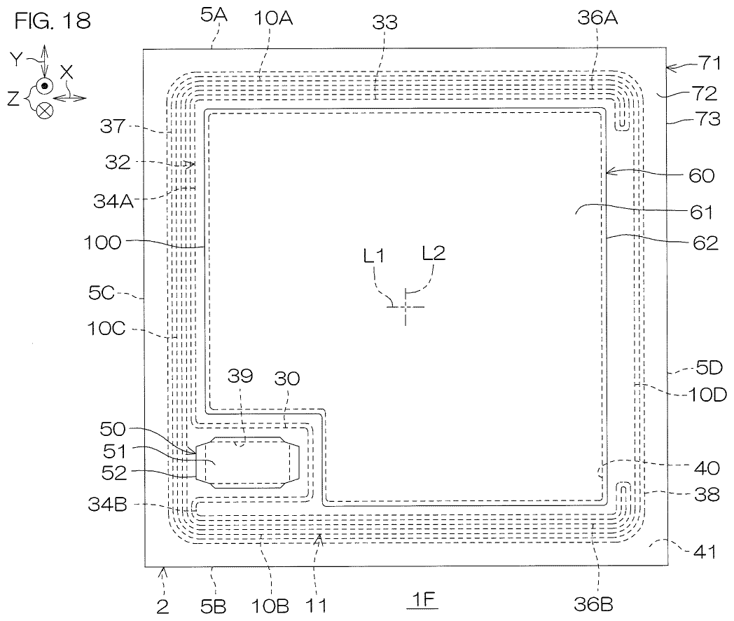

FIG. 18 is a plan view showing a semiconductor device 1F according to an sixth embodiment. With reference to FIG. 18, the semiconductor device 1F has a modified mode of the semiconductor device 1A. Specifically, the semiconductor device 1F has the gate electrode 30 arranged on a region along an arbitrary corner portion of the chip 2.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged at a position offset from both of the first straight line L1 and the second straight line L2. The gate electrode 30 is arranged at a region along a corner portion that connects the second side surface 5B and the third side surface 5C in plan view, in this embodiment.

The plurality of drawer electrode portions 34A, 34B of the source electrode 32 aforementioned sandwich the gate electrode 30 from both sides of the second direction Y in plan view as with the case of the first embodiment. The first drawer electrode portion 34A is drawn out from the body electrode portion 33 with a first planar area. The second drawer electrode portion 34B is drawn out from the body electrode portion 33 with a second planar area less than the first planar area. As a matter of course, the source electrode 32 does not may have the second drawer electrode portion 34B and may only include the body electrode portion 33 and the first drawer electrode portion 34A.

The gate terminal electrode 50 aforementioned is arranged on the gate electrode 30 as with the case of the first embodiment. The gate terminal electrode 50 is arranged at a region along an arbitrary corner portion of the chip 2, in this embodiment. That is, the gate terminal electrode 50 is arranged at a position offset from both of the first straight line L1 and the second straight line L2 in plan view. The gate terminal electrode 50 is arranged at the region along the corner portion that connects the second side surface 5B and the third side surface 5C in plan view, in this embodiment.

The source terminal electrode 60 aforementioned has the drawer terminal portion 100 that is drawn out onto the first drawer electrode portion 34A, in this embodiment. The source terminal electrode 60 does not have the drawer terminal portion 100 that is drawn out onto the second drawer electrode portion 34B, in this embodiment. The drawer terminal portions 100 thereby faces the gate terminal electrode 50 from one side of the second direction Y. The source terminal electrode 60 has portions that face the gate terminal electrode 50 from two directions including the first direction X and the second direction Y by having the drawer terminal portion 100.

As described above, the same effects as those of the semiconductor device 1A are also achieved with the semiconductor device 1F. In the manufacturing method for the semiconductor device 1F, the wafer structure 80 in which structures corresponding to the semiconductor device 1F are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1F. The structure in which the gate electrode 30 and the gate terminal electrode 50 are arranged at the corner portion of the chip 2 may be applied to the second to fifth embodiments.

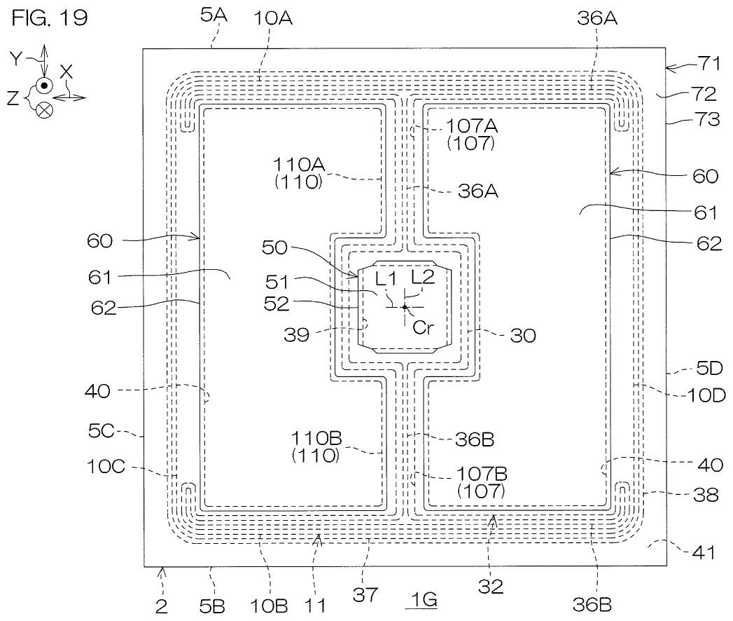

FIG. 19 is a plan view showing a semiconductor device 1G according to a seventh embodiment. With reference to FIG. 19, the semiconductor device 1G has a modified mode of the semiconductor device 1A. Specifically, the semiconductor device 1G has the gate electrode 30 arranged at the central portion of the first main surface 3 (the active surface 8) in plan view.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged such as to overlap an intersecting portion Cr of the first straight line L1 and the second straight line L2. The source electrode 32 aforementioned is formed in an annular shape (specifically, a quadrangle annular shape) surrounding the gate electrode 30 in plan view, in this embodiment.

The semiconductor device 1G includes a plurality of gap portions 107A, 107B that are formed in the source electrode 32. The plurality of gap portions 107A, 107B includes a first gap portions 107A and a second gap portions 107B. The first gap portion 107A crosses a portion of the source electrode 32 that extends in the first direction X in a region on one side (the first side surface 5A side) of the source electrode 32 in the second direction Y. The first gap portion 107A faces the gate electrode 30 in the second direction Y in plan view.

The second gap portion 107B crosses a portion of the source electrode 32 that extends in the first direction X in a region on the other side (the second side surface 5B side) of the source electrode 32 in the second direction Y. The second gap portion 107B faces the gate electrode 30 in the second direction Y in plan view. The second gap portion 107B faces the first gap portion 107A with the gate electrode 30 interposed therebetween in plan view, in this embodiment.

The first gate wiring 36A aforementioned is drawn out into the first gap portion 107A from the gate electrode 30. Specifically, the first gate wiring 36A has a portion extending as a band shape in the second direction Y inside the first gap portion 107A and a portion extending as a band shape in the first direction X along the first side surface 5A (the first connecting surface 10A). The second gate wiring 36B aforementioned is drawn out into the second gap portion 107B from the gate electrode 30. Specifically, the second gate wiring 36B has a portion extending as a band shape in the second direction Y inside the second gap portion 107B and a portion extending as a band shape in the first direction X along the second side surface 5B (the second connecting surface 10B).

The plurality of gate wirings 36A, 36B intersect (specifically, perpendicularly intersect) both end portions of the plurality of gate structures 15 as with the case of the first embodiment. The plurality of gate wirings 36A, 36B penetrate the interlayer insulating film 27 and are electrically connected to the plurality of gate structures 15. The plurality of gate wirings 36A, 36B may be directly connected the plurality of gate structures 15, or may be electrically connected to the plurality of gate structures 15 via a conductor film.

The source wiring 37 aforementioned is drawn out from a plural portions of the source electrode 32 and surrounds the gate electrode 30, the source electrode 32 and the gate wirings 36A, 36B. As a matter of course, the source wiring 37 may be drawn out from a single portion of the source electrode 32 as with the case of the first embodiment.

The upper insulating film 38 aforementioned includes a plurality of gap covering portions 110A, 110B each cover the plurality of gap portions 107A, 107B, in this embodiment. The plurality of gap covering portions 110A, 110B includes a first gap covering portion 110A and a second gap covering portion 110B. The first gap covering portion 110A covers a whole region of the first gate wiring 36A in the first gap portion 107A. The second gap covering portion 110B covers a whole region of the second gate wiring 36B in the second gap portion 107B. The plurality of gap covering portions 110A, 110B are each drawn out onto the source electrode 32 from inside the plurality of gap portions 107A, 107B such as to cover the peripheral edge portion of the source electrode 32.

The gate terminal electrode 50 aforementioned is arranged on the gate electrode 30 as with the case of the first embodiment. The gate terminal electrode 50 is arranged on the central portion of the first main surface 3 (the active surface 8), in this embodiment. That is, when the first straight line L1 (see two-dot chain line portion) crossing the central portion of the first main surface 3 in the first direction X and the second straight line L2 (see two-dot chain line portion) crossing the central portion of the first main surface 3 in the second direction Y are set, the gate terminal electrode 50 is arranged such as to overlap the intersecting portion Cr of the first straight line L1 and the second straight line L2.

The semiconductor device 1G includes a plurality of source terminal electrodes 60 that are arranged on the source electrode 32, in this embodiment. The plurality of source terminal electrodes 60 are each arranged on the source electrode 32 at intervals from the plurality of gap portions 107A, 107B and face each other in the first direction X in plan view. The plurality of source terminal electrodes 60 are arranged such as to expose the plurality of gap portions 107A, 107B, in this embodiment.

The plurality of source terminal electrodes 60 are each formed in a band shape (specifically, C-letter shape curved along the gate terminal electrode 50) in plan view, in this embodiment. The planar shapes of the plurality of source terminal electrodes 60 are arbitrary, and may each be formed in a quadrangle shape, a polygonal shape other than the quadrangle shape, a circular shape or an elliptical shape. The plurality of source terminal electrodes 60 may each include the second protrusion portion 63 that is arranged on the gap covering portion 110A, 110B of the upper insulating film 38. The sealing insulator 71 aforementioned covers the plurality of gap portions 107A, 107B at a region between the plurality of source terminal electrodes 60, in this embodiment. The sealing insulator 71 covers the plurality of gap covering portion 110A, 110B at a region between the plurality of source terminal electrodes 60, in this embodiment. That is, the sealing insulator 71 covers the plurality of gate wiring 36A, 36B with the plurality of gap covering portion 110A, 110B interposed therebetween.

An example in which the upper insulating film 38 has the gap covering portion 110A, 110B has been shown, in this embodiment. However, the presence or the absence of the plurality of gap covering portion 110A, 110B is arbitrary and the upper insulating film 38 without the plurality of gap covering portion 110A, 110B may be formed. In this case, the plurality of source terminal electrodes 60 are formed on the source electrode 32 such as to expose the gate wirings 36A, 36B.

The sealing insulator 71 directly covers the gate wirings 36A, 36B and electrically isolates the gate wirings 36A, 36B from the source electrode 32. The sealing insulator 71 directly covers a part of the interlayer insulating film 27 exposed from a region between the source electrode 32 and the gate wirings 36A, 36B inside the plurality of gap portions 107A, 107B.

As described above, the same effects as those of the semiconductor device 1A are also achieved with the semiconductor device 1G. In the manufacturing method for the semiconductor device 1G, the wafer structure 80 in which structures corresponding to the semiconductor device 1G are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1G. The structure in which the gate electrode 30 and the gate terminal electrode 50 are arranged at the central portion of the chip 2 may be applied to the second to sixth embodiments.

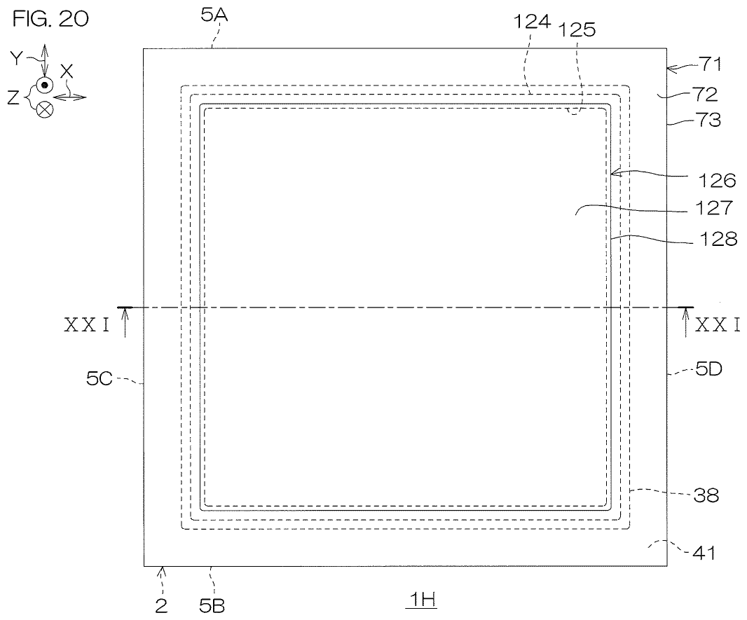

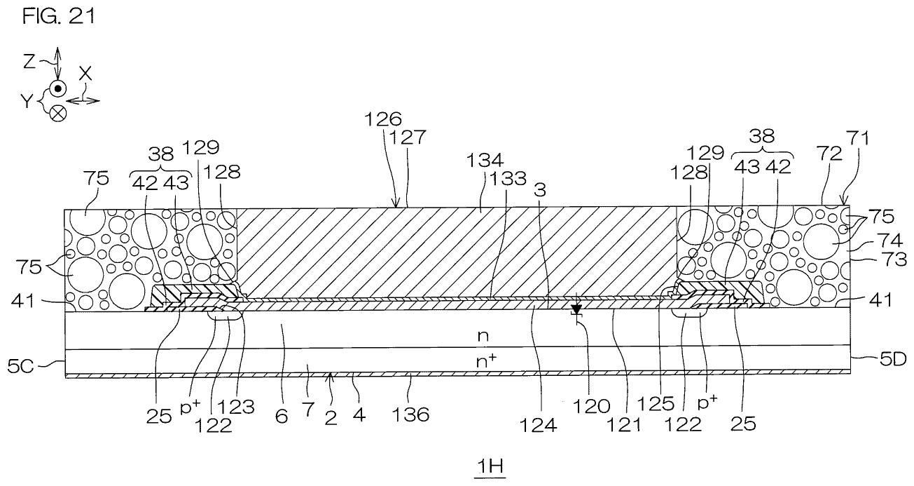

FIG. 20 is a plan view showing a semiconductor device 1H according to an eighth embodiment. FIG. 21 is a cross sectional view taken along XXI-XXI line shown in FIG. 20. The semiconductor device 1H includes the chip 2 aforementioned. The chip 2 is free from the mesa portion 11 in this embodiment and has the flat first main surface 3. The semiconductor device 1J has an SBD (Schottky Barrier Diode) structure 120 that is formed in the chip 2 as an example of a diode.

The semiconductor device 1H includes a diode region 121 of the n-type that is formed in an inner portion of the first main surface 3. The diode region 121 is formed by using a part of the first semiconductor region 6, in this embodiment. The semiconductor device 1H includes a guard region 122 of the p-type that demarcates the diode region 121 from other regions at the first main surface 3. The guard region 122 is formed in a surface layer portion of the first semiconductor region 6 at the interval from a peripheral edge of the first main surface 3. The guard region 122 is formed in an annular shape (in this embodiment, a quadrangle annular shape) surrounding the diode region 121 in plan view, in this embodiment. The guard region 122 has an inner end portion on the diode region 121 side and an outer end portion on the peripheral edge side of the first main surface 3.

The semiconductor device 1H includes the main surface insulating film 25 aforementioned that selectively covers the first main surface 3. The main surface insulating film 25 has a diode opening 123 that exposes the diode region 121 and the inner end portion of the guard region 122. The main surface insulating film 25 is formed at an interval inward from the peripheral edge of the first main surface 3 and exposes the first main surface 3 (the first semiconductor region 6) from the peripheral edge portion of the first main surface 3. As a matter of course, the main surface insulating film 25 may cover the peripheral edge portion of the first main surface 3. In this case, the peripheral edge portion of the main surface insulating film 25 may be continuous to the first to fourth side surfaces 5A to 5D.

The semiconductor device 1H includes a first polar electrode 124 (main surface electrode) that is arranged on the first main surface 3. The first polar electrode 124 is an “anode electrode”, in this embodiment. The first polar electrode 124 is arranged at an interval inward from the peripheral edge of the first main surface 3. The first polar electrode 124 is formed in a quadrangle shape along the peripheral edge of the first main surface 3 in plan view, in this embodiment. The first polar electrode 124 enters into the diode opening 123 from on the main surface insulating film 25, and is electrically connected to the first main surface 3 and the inner end portion of guard region 122.

The first polar electrode 124 forms a Schottky junction with the diode region 121 (the first semiconductor region 6). The SBD structure 120 is thereby formed. A planar area of the first polar electrode 124 is preferably not less than 50% of the first main surface 3. The planar area of the first polar electrode 124 is particularly preferably not less than 75% of the first main surface 3. The first polar electrode 124 may have a thickness of not less than 0.5 μm and not more than 15 μm.

The first polar electrode 124 may have a laminated structure that includes a Ti-based metal film and an Al-based metal film. The Ti-based metal film may have a single layered structure consisting of a Ti film or a TiN film. The Ti-based metal film may have a laminated structure that includes the Ti film and the TiN film laminated with an arbitrary order. The Al-based metal film is preferably thicker than the Ti-based metal film. The Al-based metal film may include at least one of a pure Al film (Al film with a purity of not less than 99%), an AlCu alloy film, an AlSi alloy film and an AlSiCu alloy film.

The semiconductor device 1H includes the upper insulating film 38 aforementioned that selectively covers the main surface insulating film 25 and the first polar electrode 124. The upper insulating film 38 has the laminated structure that includes the inorganic insulating film 42 and the organic insulating film 43 laminated in that order from the chip 2 side as with the case of the first embodiment. The upper insulating film 38 has a contact opening 125 exposing an inner portion of the first polar electrode 124 and covers a peripheral edge portion of the first polar electrode 124 over an entire circumference in plan view, in this embodiment. The contact opening 125 is formed in a quadrangle shape in plan view, in this embodiment.

The upper insulating film 38 is formed at an interval inward from the peripheral edge of the first main surface 3 (the first to fourth side surfaces 5A to 5D) and defines the dicing street 41 with the peripheral edge of the first main surface 3. The dicing street 41 is formed in a band shape extending along the peripheral edge of the first main surface 3 in plan view. The dicing street 41 is formed in an annular shape (specifically, a quadrangle annular shape) surrounding the inner portion of the first main surface 3 in plan view, in this embodiment.

The dicing street 41 exposes the first main surface 3 (the first semiconductor region 6), in this embodiment. As a matter of course, in a case in which the main surface insulating film 25 covers the peripheral edge portion of the first main surface 3, the dicing street 41 may expose the main surface insulating film 25. The upper insulating film 38 preferably has a thickness exceeding the thickness of the first polar electrode 124. The thickness of the upper insulating film 38 may be less than the thickness of the chip 2.

The semiconductor device 1H includes a terminal electrode 126 that is arranged on the first polar electrode 124. The terminal electrode 126 is erected in a columnar shape on a portion of the first polar electrode 124 that is exposed from the contact opening 125. The terminal electrode 126 may have an area less than the area of the first polar electrode 124 in plan view, and may be arranged on an inner portion of the first polar electrode 124 at an interval from the peripheral edge of the first polar electrode 124. The terminal electrode 126 is formed in a polygonal shape (in this embodiment, quadrangle shape) having four sides parallel to the first to fourth side surfaces 5A to 5D in plan view, in this embodiment.

The terminal electrode 126 has a terminal surface 127 and a terminal side wall 128. The terminal surface 127 flatly extends along the first main surface. The terminal surface 127 may consist of a ground surface with grinding marks. The terminal side wall 128 is located on the upper insulating film 38 (specifically, the organic insulating film 43), in this embodiment.

That is, the terminal electrode 126 has a portion in contact with the inorganic insulating film 42 and the organic insulating film 43. The terminal side wall 128 extends substantially vertically to the normal direction Z. Here, “substantially vertically” includes a mode that extends in the laminate direction while being curved (meandering). The terminal side wall 128 includes a portion that faces the first polar electrode 124 with the upper insulating film 38 interposed therebetween. The terminal side wall 128 preferably consists of a smooth surface without a grinding mark.

The terminal electrode 126 has a protrusion portion 129 that outwardly protrudes at a lower end portion of the terminal side wall 128. The protrusion portion 129 is formed at a region on the upper insulating film 38 (the organic insulating film 43) side than an intermediate portion of the terminal side wall 128. The protrusion portion 129 extends along the outer surface of the upper insulating film 38, and is formed in a tapered shape in which a thickness gradually decreases toward the tip portion from the terminal side wall 128 in cross sectional view. The protrusion portion 129 therefore has a sharp-shaped tip portion with an acute angle. As a matter of course, the protrusion portion 129 without the protrusion portion 129 may be formed.

The terminal electrode 126 preferably has a thickness exceeding the thickness of the first polar electrode 124. The thickness of the terminal electrode 126 particularly preferably exceeds the thickness of the upper insulating film 38. The thickness of the terminal electrode 126 exceeds the thickness of the chip 2, in this embodiment. As a matter of course, the thickness of the terminal electrode 126 may be less than the thickness of the chip 2.

The thickness of the terminal electrode 126 may be not less than 10 μm and not more than 300 μm. The thickness of the terminal electrode 126 is preferably not less than 30 μm. The thickness of the terminal electrode 126 is particularly preferably not less than 80 μm and not more than 200 μm. The terminal electrode 126 preferably has a planar area of not less than 50% of the first main surface 3. The terminal electrode 126 particularly preferably has a planar area of not less than 75% of the first main surface 3.

The terminal electrode 126 has a laminated structure that includes a first conductor film 133 and a second conductor film 134 laminated in that order from the first polar electrode 124 side, in this embodiment. The first conductor film 133 may include a Ti-based metal film. The first conductor film 133 may have a single layered structure consisting of a Ti film or a TiN film.

The first conductor film 133 may have a laminated structure that includes the Ti film and the TiN film laminated with an arbitrary order. The first conductor film 133 has a thickness less than the thickness of the first polar electrode 124. The first conductor film 133 covers the first polar electrode 124 in a film shape inside the contact opening 125 and is drawn out onto the upper insulating film 38 in a film shape. The first conductor film 133 forms a part of the protrusion portion 129. The first conductor film 133 does not necessarily have to be formed and may be omitted.

The second conductor film 134 forms a body of the terminal electrode 126. The second conductor film 134 may include a Cu-based metal film. The Cu-based metal film may be a pure Cu film (Cu film with a purity of not less than 99%) or Cu alloy film. The second conductor film 134 includes a pure Cu plating film, in this embodiment. The second conductor film 134 preferably has a thickness exceeding the thickness of the first polar electrode 124. The thickness of the second conductor film 134 particularly preferably exceeds the thickness of the upper insulating film 38. The thickness of the second conductor film 134 exceeds the thickness of the chip 2, in this embodiment.

The second conductor film 134 covers the first polar electrode 124 with the first conductor film 133 interposed therebetween inside the contact opening 125, and is drawn out onto the upper insulating film 38 in a film shape with the first conductor film 133 interposed therebetween. The second conductor film 134 forms a part of the protrusion portion 129. That is, the protrusion portion 129 has a laminated structure that includes the first conductor film 133 and the second conductor film 134. The second conductor film 134 has a thickness exceeding a thickness of the first conductor film 133 in the protrusion portion 129.

The semiconductor device 1H includes the sealing insulator 71 aforementioned that covers the first main surface 3. The sealing insulator 71 includes the matrix resin 74, the plurality of fillers 75 and the plurality of flexible particles 76 (flexible agent). The sealing insulator 71 covers a periphery of the terminal electrode 126 such as to expose a part of the terminal electrode 126 on the first main surface 3, in this embodiment. Specifically, the sealing insulator 71 exposes the terminal surface 127 and covers the terminal side wall 128. The sealing insulator 71 covers the protrusion portion 129 and faces the upper insulating film 38 with the protrusion portion 129 interposed therebetween, in this embodiment. The sealing insulator 71 suppresses a dropout of the terminal electrode 126.

The sealing insulator 71 has a portion that directly covers the upper insulating film 38. The sealing insulator 71 covers the first polar electrode 124 with the upper insulating film 38 interposed therebetween. The sealing insulator 71 covers the dicing street 41 that is demarcated by the upper insulating film 38 at the peripheral edge portion of the first main surface 3. The sealing insulator 71 directly covers the first main surface 3 (the first semiconductor region 6) at the dicing street 41, in this embodiment. As a matter of course, in a case in which the main surface insulating film 25 is exposed from the dicing street 41, the sealing insulator 71 may directly cover the main surface insulating film 25 at the dicing street 41.

The sealing insulator 71 preferably has a thickness exceeding the thickness of the first polar electrode 124. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm.

The sealing insulator 71 has the insulating main surface 72 and the insulating side wall 73. The insulating main surface 72 flatly extends along the first main surface 3. The insulating main surface 72 forms a single flat surface with the terminal surface 127. The insulating main surface 72 may consist of a ground surface with grinding marks. In this case, the insulating main surface 72 preferably forms a single ground surface with the terminal surface 127.

The insulating side wall 73 extends toward the chip 2 from the peripheral edge of the insulating main surface 72 and is continuous to the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The semiconductor device 1H includes a second polar electrode 136 (second main surface electrode) that covers the second main surface 4. The second polar electrode 136 is a “cathode electrode”, in this embodiment. The second polar electrode 136 is electrically connected to the second main surface 4. The second polar electrode 136 forms an ohmic contact with the second semiconductor region 7 exposed from the second main surface 4. The second polar electrode 136 may cover a whole region of the second main surface 4 such as to be continuous with the peripheral edge of the chip 2 (the first to fourth side surfaces 5A to 5D).

The second polar electrode 136 may cover the second main surface 4 at an interval from the peripheral edge of the chip 2. The second polar electrode 136 is configured such that a voltage of not less than 500 V and not more than 3000 V is to be applied between the terminal electrode 126 and second polar electrode 136. That is, the chip 2 is formed such that the voltage of not less than 500 V and not more than 3000 V is to be applied between the first main surface 3 and the second main surface 4.

As described above, the semiconductor device 1H includes the chip 2, the first polar electrode 124 (main surface electrode), the terminal electrode 126 and the sealing insulator 71. The chip 2 has the first main surface 3. The first polar electrode 124 is arranged on the first main surface 3 at an interval from the periphery of the first main surface 3. The terminal electrode 126 is arranged on the first polar electrode 124.

The sealing insulator 71 covers the periphery of the terminal electrode 126 on the first main surface 3 such as to expose a part of the terminal electrode 126. The sealing insulator 71 includes the matrix resin 74 and the plurality of fillers 75. The plurality of fillers 75 are added into the matrix resin 74 such that the ratio of the total cross-sectional area with respect to the unit cross-sectional area is higher than the ratio of the cross-sectional area of the matrix resin 74 with respect to the unit cross-sectional area.

According to this structure, it is possible to improve the mechanical strength of the sealing insulator 71 and suppress a deformation of the chip 2 caused by the stress of the sealing insulator 71 and fluctuations in electrical characteristics. In addition, since the stress of the sealing insulator 71 can be suppressed, the relatively thick sealing insulator 71 can be formed. That is, it is possible to protect the object to be sealed from the first main surface 3 side while suppressing a deformation of the chip 2 caused by the stress of the sealing insulator 71 and fluctuations in electrical characteristics.

According to this structure, an object to be sealed can be protected from the external force and the humidity by the sealing insulator 71. That is, the object to be sealed can be protected from a damage due to the external force and deterioration due to the humidity. It is therefore possible to suppress shape defects and fluctuations in electrical characteristics. As a result, it is possible to provide the semiconductor device 1H capable of improving reliability.

Thus, the same effects as those of the semiconductor device 1A are also achieved with the semiconductor device 1H. In the manufacturing method for the semiconductor device 1H, the wafer structure 80 in which structures corresponding to the semiconductor device 1H are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1H.

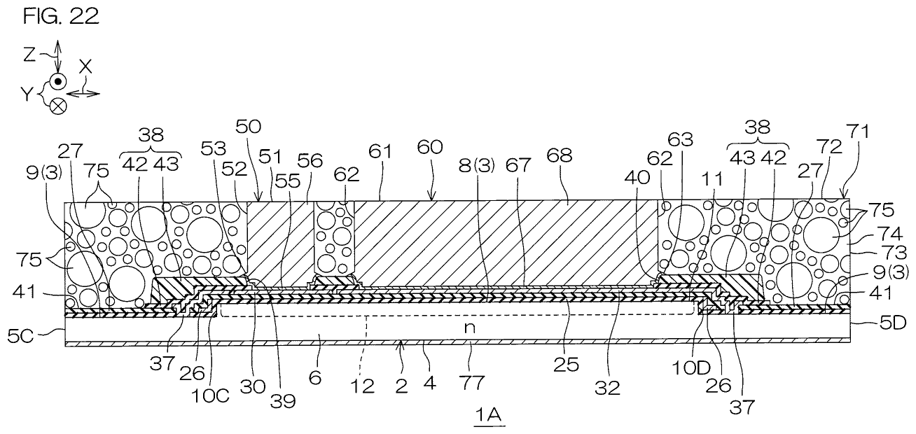

Hereinafter, modified examples to be applied to each embodiment shall be shown. FIG. 22 is a cross sectional view showing a modified example of the chip 2 to be applied to each of the embodiments. In FIG. 22, a mode in which the modified example of the chip 2 is applied to the semiconductor device 1A is shown as an example. However, the modified example of the chip 2 may be applied to any one of the second to eighth embodiments. With reference to FIG. 22, the semiconductor device 1A does not have the second semiconductor region 7 inside the chip 2 and may only have the first semiconductor region 6 inside the chip 2.

In this case, the first semiconductor region 6 is exposed from the first main surface 3, the second main surface 4 and the first to fourth side surfaces 5A to 5D of the chip 2. That is, the chip 2 has a single layered structure that does not have the semiconductor substrate and that consists of the epitaxial layer, in this embodiment. The chip 2 having such a structure is formed by fully removing the second semiconductor region 7 (the semiconductor substrate) in the step shown in FIG. 10H aforementioned.

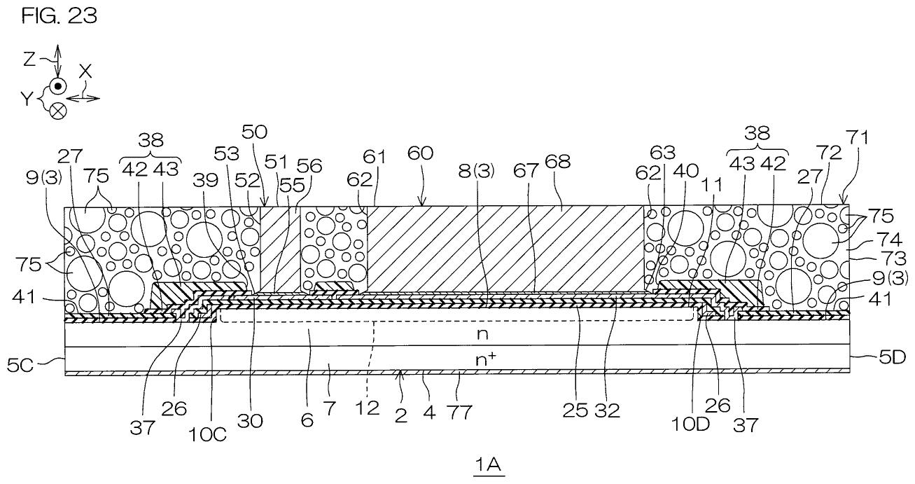

FIG. 23 is a cross sectional view showing a modified example of the sealing insulator 71 to be applied to each of the embodiments. In FIG. 23, a mode in which the modified example of the sealing insulator 71 is applied to the semiconductor device 1A is shown as an example. However, the modified example of the sealing insulator 71 may be applied to any one of the second to tenth embodiments. With reference to FIG. 23, the semiconductor device 1A may include the sealing insulator 71 that covers a whole region of the upper insulating film 38.

In this case, in the first to seventh embodiments, the gate terminal electrode 50 and the source terminal electrode 60 that are not in contact with the upper insulating film 38 are formed. In this case, the sealing insulator 71 may have a portion that directly covers the gate electrode 30 and the source electrode 32. On the other hand, in the eighth embodiment, the terminal electrode 126 that is not in contact with the upper insulating film 38 is formed. In this case, the sealing insulator 71 may have a portion that directly covers the first polar electrode 124.

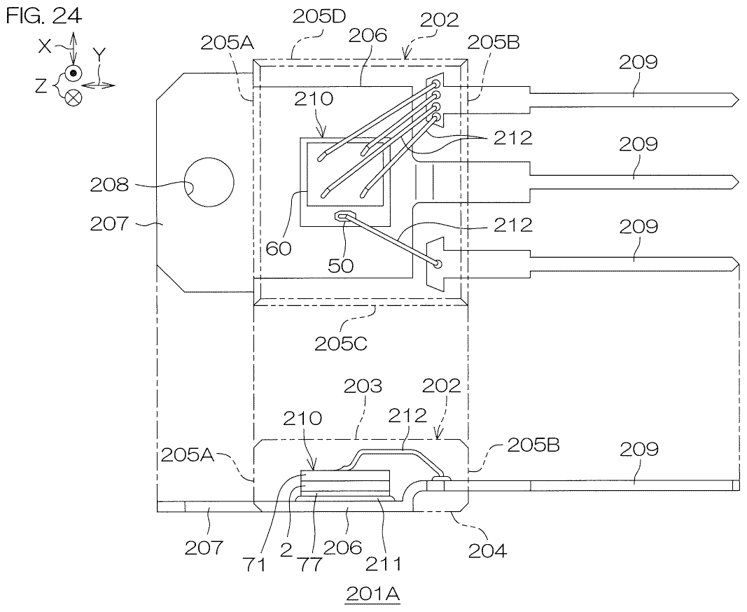

Hereinafter, configuration examples of packages to which any one or plural of the semiconductor devices 1A to 1H according to the first to eighth embodiments are to be incorporated shall be shown. FIG. 24 is a plan view showing a package 201A to which any one of the semiconductor devices 1A to 1G according to the first to seventh embodiments is to be incorporated. The package 201A may be referred to as a “semiconductor package” or a “semiconductor module”.

With reference to FIG. 24, the package 201A includes a package body 202 of a rectangular parallelepiped shape. The package body 202 consists of a mold resin and includes a matrix resin (for example, epoxy resin), a plurality of fillers and a plurality of flexible particles (flexible agent) as with the sealing insulator 71. The package body 202 has a first surface 203 on one side, the second surface 204 on the other side, and first to fourth side walls 205A to 205D connecting the first surface 203 and the second surface 204.

The first surface 203 and the second surface 204 are each formed in a quadrangle shape in plan view as viewed from their normal direction Z. The first side wall 205A and the second side wall 205B extend in the first direction X and oppose in the second direction Y orthogonal to the first direction X. The third side wall 205C and the fourth side wall 205D extend in the second direction Y and oppose in the first direction X.

The package 201A includes a metal plate 206 (conductor plate) that is arranged inside the package body 202. The metal plate 206 may be referred to as a “die pad”. The metal plate 206 is formed in a quadrangle shape (specifically, rectangular shape) in plan view. The metal plate 206 includes a drawer board part 207 that is drawn out from the first side wall 205A to an outside of the package body 202. The drawer board part 207 has a through hole 208 of a circular shape. The metal plate 206 may be exposed from the second surface 204.

The package 201A includes a plurality of (in this embodiment, three) lead terminals 209 that are pulled out from an inside of the package body 202 to the outside of the package body 202. The plurality of lead terminals 209 are arranged on the second side wall 205B side. The plurality of lead terminals 209 are each formed in a band shape extending in an orthogonal direction to the second side wall 205B (that is, the second direction Y). The lead terminals 209 on both sides of the plurality of lead terminals 209 are arranged at intervals from the metal plate 206, and the lead terminals 209 on a center is integrally formed with the metal plate 206. A position of the lead terminal 209 that is to be connected to the metal plate 206 is arbitrary.

The package 201A includes a semiconductor device 210 that is arranged on the metal plate 206 inside the package body 202. The semiconductor device 210 consists of any one of the semiconductor devices 1A to 1G according to the first to seventh embodiments. The semiconductor device 210 is arranged on the metal plate 206 in a posture with the drain electrode 77 opposing the metal plate 206, and is electrically connected to the metal plate 206.

The package 201A includes a conductive adhesive 211 that is interposed between the drain electrode 77 and the metal plate 206 and that connects the semiconductor device 210 to the metal plate 206. The conductive adhesive 211 may include a solder or a metal paste. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The package 201A includes at least one (in this embodiment, a plurality of) conducting wires 212 (conductive connection member) that are electrically connected to the lead terminals 209 and the semiconductor device 210 inside the package body 202. The conducting wires 212 each consists of a metal wire (that is, bonding wire), in this embodiment. The conducting wires 212 may include at least one of a gold wire, a copper wire and an aluminum wire. As a matter of course, the conducting wires 212 may each consist of a metal plate such as a metal clip, instead of the metal wire.

At least one (in this embodiment, one) conducting wire 212 is electrically connected to the gate terminal electrode 50 and the lead terminal 209. At least one (in this embodiment, four) conducting wires 212 are electrically connected to the source terminal electrode 60 and the lead terminal 209. In a case in which the source terminal electrode 60 includes the sense terminal electrode 103 (see FIG. 12), the lead terminal 209 corresponding to the sense terminal electrode 103, and the conducting wire 212 corresponding to the sense terminal electrode 103 and the lead terminals 209 may be provided.

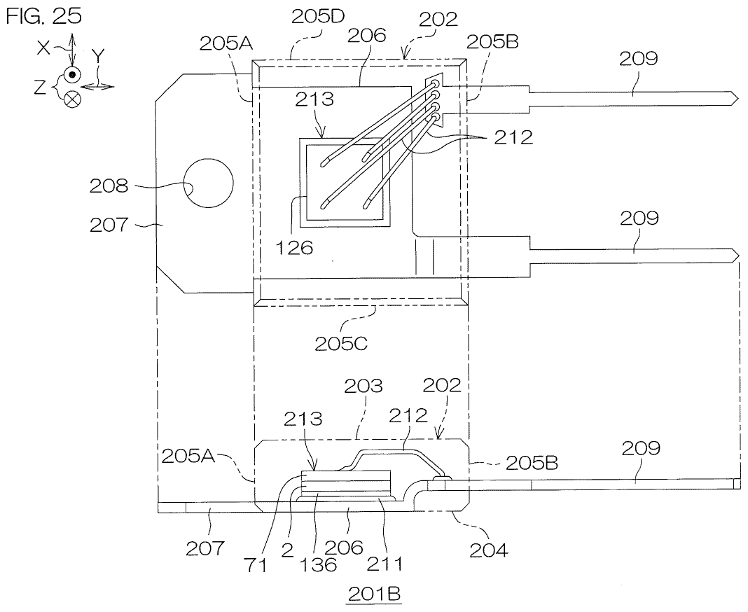

FIG. 25 is a plan view showing a package 201B to which any one of the semiconductor device 1H according to the eighth embodiment is to be incorporated. The package 201B may be referred to as a “semiconductor package” or a “semiconductor module”. With reference to FIG. 25, the package 201B includes the package body 202, the metal plate 206, the plurality (in this embodiment, two) lead terminals 209, a semiconductor device 213, the conductive adhesive 211, and the plurality conducting wires 212. Hereinafter, points different from those of the package 201A shall be described.

One lead terminal 209 of the plurality of lead terminals 209 is arranged at an interval from the metal plate 206, and the other lead terminals 209 is integrally formed with the metal plate 206. The semiconductor device 213 is arranged on the metal plate 206 inside the package body 202. The semiconductor device 213 consists of any one of the semiconductor device 1H according to the eighth embodiment. The semiconductor device 213 is arranged on the metal plate 206 in a posture with the second polar electrode 136 opposing to the metal plate 206, and is electrically connected to the metal plate 206.

The conductive adhesive 211 is interposed between the second polar electrode 136 and the metal plate 206 and connects the semiconductor device 213 to the metal plate 206. At least one (in this embodiment, four) conducting wires 212 are electrically connected to the terminal electrode 126 and the lead terminal 209.

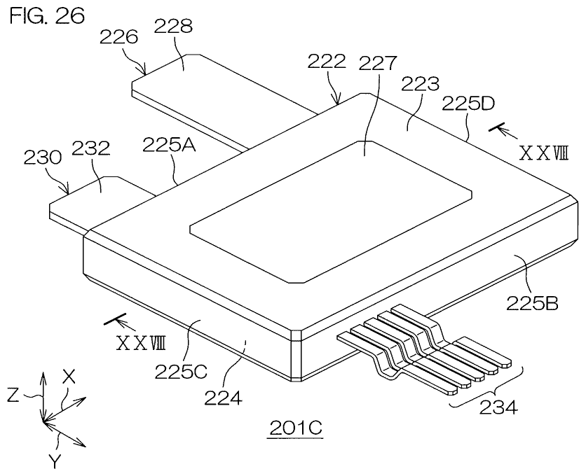

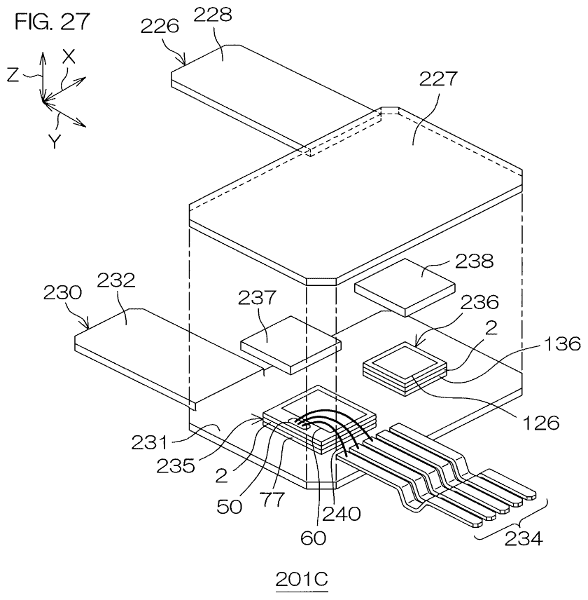

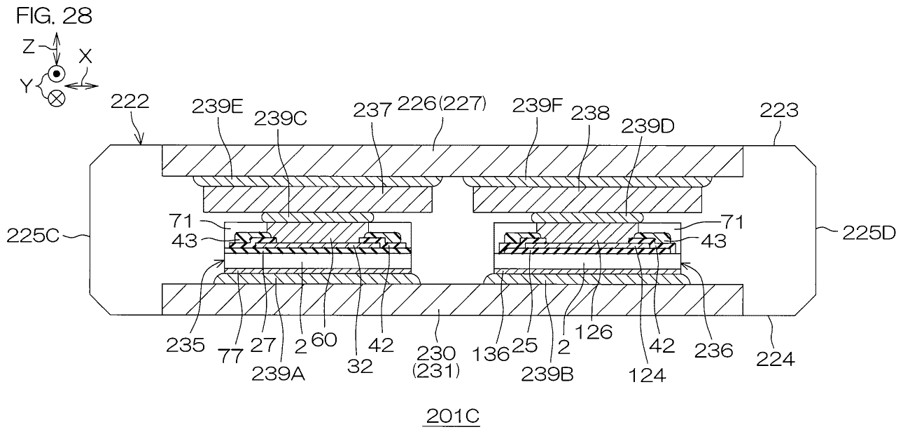

FIG. 26 is a perspective view showing a package 201C to which any one of the semiconductor devices 1A to 1G according to the first to seventh embodiments and the semiconductor device 1H according to the eighth embodiment are to be incorporated. FIG. 27 is an exploded perspective view of the package 201C shown in FIG. 26. FIG. 28 is a cross sectional view taken along XXVIII-XXVIII line shown in FIG. 26. The package 201C may be referred to as a “semiconductor package” or a “semiconductor module”.

With reference to FIG. 26 to FIG. 28, the package 201C includes a package body 222 of a rectangular parallelepiped shape. The package body 222 consists of a mold resin and includes a matrix resin (for example, epoxy resin), a plurality of fillers and a plurality of flexible particles (flexible agent) as with the sealing insulator 71. The package body 222 has a first surface 223 on one side, the second surface 224 on the other side, and first to fourth side walls 225A to 225D connecting the first surface 223 and the second surface 224.

The first surface 223 and the second surface 224 each formed in a quadrangle shape (in this embodiment, rectangular shape) in plan view as viewed from their normal direction Z. The first side wall 225A and the second side wall 225B extend in the first direction X along the first surface 223 and oppose in the second direction Y. The first side wall 225A and the second side wall 225B each forms a long side of the package body 222. The third side wall 225C and the fourth side wall 225D extend in the second direction Y and oppose in the first direction X. The third side wall 225C and the fourth side wall 225D each forms a short side of the package body 222.

The package 201C includes a first metal plate 226 that is arranged inside and outside the package body 222. The first metal plate 226 is arranged on the first surface 223 side of the first surface 223 and includes a first pad portion 227 and a first lead terminal 228. The first pad portion 227 is formed in a rectangular shape extending in the first direction X inside the package body 222 and exposes the first surface 223.

The first lead terminal 228 is pulled out from the first pad portion 227 toward the first side wall 225A in a band shape extending in the second direction Y, and penetrates the first side wall 225A to be exposed from the package body 222. The first lead terminal 228 is arranged on the fourth side wall 225D side in plan view. The first lead terminal 228 is exposed from the first side wall 225A at a position at intervals from the first surface 223 and the second surface 224.

The package 201C includes a second metal plate 230 that is arranged inside and outside the package body 222. The second metal plate 230 is arranged on the second surface 224 side of the package body 222 at an interval from the first metal plate 226 in the normal direction Z and includes the second pad portion 231 and the second lead terminal 232. The second pad portion 231 is formed in a rectangular shape extending in the first direction X inside the package body 222 and exposes from the second surface 224.

The second lead terminal 232 is pulled out from the second pad portion 231 to the first side wall 225A in a band shape extending in the second direction Y, and penetrates the first side wall 225A to be exposed from the package body 222. The second lead terminal 232 arranged on the third side wall 225C side in plan view. The second lead terminal 232 is exposed from the first side wall 225A at a position at intervals from the first surface 223 and the second surface 224.

The second lead terminal 232 is pulled out at a thickness position different from a thickness position of the first lead terminal 228, in regard to the normal direction Z. The second lead terminal 232 is formed at an interval from the first lead terminal 228 to the second surface 224 side, and does not oppose the first lead terminal 228 in the first direction X, in this embodiment. The second lead terminal 232 has a length different from a length of the first lead terminal 228, in regard to the second direction Y.

The package 201C includes a plurality of (in this embodiment, five) third lead terminals 234 that are pulled out from inside of the package body 222 to outside of the package body 222. The plurality of third lead terminals 234 are arranged in a thickness range between the first pad portion 227 and the second pad portion 231, in this embodiment. The plurality of third lead terminals 234 are each pulled out from inside of the package body 222 toward the second side wall 225B in a band shape extending in the second direction Y, and penetrate the second side wall 225B to be exposed from the package body 222.

An arrangement of the plurality of third lead terminals 234 is arbitrary. The plurality of third lead terminals 234 are arranged on the third side wall 225C side such as to locate on the same straight line with the second lead terminal 232, in plan view, in this embodiment. The plurality of third lead terminals 234 may each have a curved section bent toward the first surface 223 and/or the second surface 224 in a portion located outside the package body 222.

The package 201C includes a first semiconductor device 235 that is arranged inside the package body 222. The first semiconductor device 235 consists of any one of the semiconductor devices 1A to 1G according to the first to seventh embodiments. The first semiconductor device 235 is arranged between the first pad portion 227 and the second pad portion 231. The first semiconductor device 235 is arranged on the third side wall 225C side in plan view. The first semiconductor device 235 is arranged on the second metal plate 230 in a posture with the drain electrode 77 opposing to the second metal plate 230 (the second pad portion 231), and is electrically connected to the second metal plate 230.

The package 201C includes a second semiconductor device 236 that is arranged inside the package body 222 at an interval from the first semiconductor device 235. The second semiconductor device 236 consists of the semiconductor device 1H according to the eighth embodiment. The second semiconductor device 236 is arranged between the first pad portion 227 and the second pad portion 231. The second semiconductor device 236 is arranged on the fourth side wall 225D side in plan view. The second semiconductor device 236 is arranged on the second metal plate 230 in a posture with the second polar electrode 136 opposing to the second metal plate 230 (the second pad portion 231), and is electrically connected to the second metal plate 230.

The package 201C includes a first conductor spacer 237 (first conductive connection member) and a second conductor spacer 238 (second conductive connection member) that are each arranged inside the package body 222. The first conductor spacer 237 is interposed between the first semiconductor device 235 and the first pad portion 227 and is electrically connected to the first semiconductor device 235 and the first pad portion 227. The second conductor spacer 238 is interposed between the second semiconductor device 236 and the first pad portion 227 and is electrically connected to the second semiconductor device 236 and the first pad portion 227.

The first conductor spacer 237 and the second conductor spacer 238 may each include a metal plate (for example, Cu-based metal plate). The second conductor spacer 238 consists of a separated member from the first conductor spacer 237 in this embodiment, but the second conductor spacer 238 may be integrally formed with the first conductor spacer 237.

The package 201C includes first to sixth conductive adhesives 239A to 239F. The first to sixth conductive adhesives 239A to 239F may each include a solder or a metal past. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The first conductive adhesive 239A is interposed between the drain electrode 77 and the second pad portion 231, and connects the first semiconductor device 235 to the second pad portion 231. The second conductive adhesive 239B is interposed between the second polar electrode 136 and the second pad portion 231, and connects the second semiconductor device 236 to the second pad portion 231.

The third conductive adhesive 239C is interposed between the source terminal electrode 60 and the first conductor spacer 237, and connects the first conductor spacer 237 to the source terminal electrode 60. The fourth conductive adhesive 239D is interposed between the terminal electrode 126 and the second conductor spacer 238, and connects the second conductor spacer 238 to the terminal electrode 126.

The fifth conductive adhesive 239E is interposed between the first pad portion 227 and the first conductor spacer 237, and connects the first conductor spacer 237 to the first pad portion 227. The sixth conductive adhesive 239F is interposed between the first pad portion 227 and the second conductor spacer 238, and connects the second conductor spacer 238 to the first pad portion 227.

The package 201C includes at least one (in this embodiment, a plurality of) conducting wires 240 (conductive connection member) that are electrically connected to the gate terminal electrode 50 of the first semiconductor device 235 and at least one (in this embodiment, a plurality of) third lead terminals 234 inside the package body 222. The conducting wires 240 each consists of a metal wire (that is, bonding wire), in this embodiment.

The conducting wires 240 may include at least one of a gold wire, a copper wire and an aluminum wire. As a matter of course, the conducting wires 240 may each consist of a metal plate such as a metal clip, instead of the metal wire. In a case in which the source terminal electrode 60 includes the sense terminal electrode 103 (see FIG. 15), a conducting wire 240 to be connected to the sense terminal electrode 103 and the third lead terminal 234 may be further provide.

An example in which the source terminal electrode 60 is connected to the first pad portion 227 via the first conductor spacers 237 has been shown, in this embodiment. However, the source terminal electrode 60 may be connected to the first pad portion 227 by the third conductive adhesive 239C without the first conductor spacer 237. Also, an example in which the terminal electrode 126 is connected to the first pad portion 227 via the second conductor spacers 238 has been shown, in this embodiment. However, the terminal electrode 126 may be connected to the first pad portion 227 by the fourth conductive adhesive 239D without the second conductor spacers 238.

Each of the above embodiments can be implemented in yet other embodiments. For example, features disclosed in the first to eighth embodiments aforementioned can be appropriately combined therebetween. That is, a configuration that includes at least two features among the features disclosed in the first to eighth embodiments aforementioned at the same time may be adopted.

In each of the above embodiments, the chip 2 having the mesa portion 11 has been shown. However, the chip 2 that does not have the mesa portion 11 and has the first main surface 3 extending in a flat may be adopted. In this case, the side wall structure 26 may be omitted.

In each of the above embodiments, the configurations that has the source wiring 37 have been shown. However, configurations without the source wiring 37 may be adopted. In each of the above embodiments, the gate structure 15 of the trench gate type that controls the channel inside the chip 2 has been shown. However, the gate structure 15 of a planar gate type that controls the channel from on the first main surface 3 may be adopted.

In each of the above embodiments, the configurations in which the MISFET structure 12 and the SBD structure 120 are formed in the different chips 2 have been shown. However, the MISFET structure 12 and the SBD structure 120 may be formed in different regions of the first main surface 3 in the same chip 2. In this case, the SBD structure 120 may be formed as a reflux diode of the MISFET structure 12.

In each of the embodiments, the configuration in which the “first conductive type” is the “n-type” and the “second conductive type” is the “p-type” has been shown. However, in each of the embodiments, a configuration in which the “first conductive type” is the “p-type” and the “second conductive type” is the “n-type” may be adopted. The specific configuration in this case can be obtained by replacing the “n-type” with the “p-type” and at the same time replacing the “p-type” with the “n-type” in the above descriptions and attached drawings.

In each of the embodiments, the second semiconductor region 7 of the “n-type” has been shown. However, the second semiconductor region 7 may be the “p-type”. In this case, an IGBT (Insulated Gate Bipolar Transistor) structure is formed instead of the MISFET structure 12. In this case, in the above descriptions, the “source” of the MISFET structure 12 is replaced with an “emitter” of the IGBT structure, and the “drain” of the MISFET structure 12 is replaced with a “collector” of the IGBT structure. As a matter of course, in a case in which the chip 2 has a single layered structure that consists of the epitaxial layer, the second semiconductor region 7 of the “p-type” may have p-type impurities introduced into a surface layer portion of the second main surface 4 of the chip 2 (the epitaxial layer) by an ion implantation method.

In each of the embodiments, the first direction X and the second direction Y are defined by the extending directions of the first to fourth side surfaces 5A to 5D. However, the first direction X and the second direction Y may be any directions as long as the first direction X and the second direction Y keep a relationship in which the first direction X and the second direction Y intersect (specifically, perpendicularly intersect) each other. For example, the first direction X may be a direction intersecting the first to fourth side surfaces 5A to 5D, and the second direction Y may be a direction intersecting the first to fourth side surfaces 5A to 5D.

Hereinafter, examples of features extracted from the present descriptions and the attached drawings shall be indicated below. Hereinafter, the alphanumeric characters in parentheses represent the corresponding components in the aforementioned embodiments, but are not intended to limit the scope of each clause to the embodiments. The “semiconductor device” in the following clauses may be replaced with a “wide bandgap semiconductor device”, an “SiC semiconductor device”, a “semiconductor switching device” or a “semiconductor rectifier device” as needed.
[A1] A semiconductor device (1A to 1G) comprising: a chip (2) that has a main surface (3); a main surface electrode (30, 32, 124) that is arranged on the main surface (3); a terminal electrode (50, 60, 126) that is arranged on the main surface electrode (30, 32, 124); and a sealing insulator (71) that covers a periphery of the terminal electrode (50, 60, 126) on the main surface (3) such as to expose a part of the terminal electrode (50, 60, 126), and that includes a matrix resin (74) and fillers (75) added into the matrix resin (74) such that a ratio of a total cross-sectional area with respect to a unit cross-sectional area is higher than a ratio of a cross-sectional area of the matrix resin (74) with respect to the unit cross-sectional area.
[A2] The semiconductor device (1A to 1G) according to A1, wherein the fillers (75) are added into the matrix resin (74) such that the ratio of the total cross-sectional area is not less than 60%.
[A3] The semiconductor device (1A to 1G) according to A1 or A2, wherein the terminal electrode (50, 60, 126) is thicker than the main surface electrode (30, 32, 124), and the sealing insulator (71) is thicker than the main surface electrode (30, 32, 124).
[A4] The semiconductor device (1A to 1G) according to any one of A1 to A3, wherein the terminal electrode (50, 60, 126) is thicker than the chip (2), and the sealing insulator (71) is thicker than the chip (2).
[A5] The semiconductor device (1A to 1G) according to any one of A1 to A4, wherein the matrix resin (74) consists of a thermosetting resin.
[A6] The semiconductor device (1A to 1G) according to any one of A1 to A5, wherein the fillers (75) are composed of one of or both of spherical objects and indeterminate objects.
[A7] The semiconductor device (1A to 1G) according to A6, wherein the fillers (75) are composed of the spherical objects.
[A8] The semiconductor device (1A to 1G) according to any one of A1 to A7, wherein the fillers (75) include at least one of ceramics, oxides, and nitrides.
[A9] The semiconductor device (1A to 1G) according to any one of A1 to A8, wherein the sealing insulator (71) includes the fillers (75) having different particle sizes.
[A10] The semiconductor device (1A to 1G) according to any one of A1 to A9, wherein the fillers (75) each have a particle size of not less than 1 nm and not more than 50 μm.
[A11] The semiconductor device (1A to 1G) according to any one of A1 to A10, wherein the fillers (75) include fillers (75a) thinner than the main surface electrode (30, 32, 124) and fillers (75b) thicker than the main surface electrode (30, 32, 124).
[A12] The semiconductor device (1A to 1G) according to any one of A1 to A11, wherein the terminal electrode (50, 60, 126) has a terminal surface (51, 61, 127) and a terminal side wall (52, 62, 128), and the sealing insulator (71) exposes the terminal surface (51, 61, 127) and covers the terminal side wall (52, 62, 128).
[A13] The semiconductor device (1A to 1G) according to A12, wherein the sealing insulator (71) has an insulating main surface (72) that forms a single flat surface with the terminal surface (51, 61, 127).
[A14] The semiconductor device (1A to 1G) according to any one of A1 to A13, wherein the chip (2) has a side surface (5A to 5D), and the sealing insulator (71) has an insulating side wall (73) that forms a single flat surface with the side surface (5A to 5D).
[A15] The semiconductor device (1A to 1G) according to any one of A1 to A14, further comprising: an insulating film (38) that partially covers the main surface electrode (30, 32, 124); wherein the sealing insulator (71) has a portion that directly covers the insulating film (38).
[A16] The semiconductor device (1A to 1G) according to A15, wherein the terminal electrode (50, 60, 126) has a portion that directly covers the insulating film (38).
[A17] The semiconductor device (1A to 1G) according to A15 or A16, wherein the insulating film (38) includes at least one of an inorganic insulating film (42) and an organic insulating film (43).
[A18] The semiconductor device (1A to 1G) according to any one of A15 to A17, wherein the insulating film (38) is thicker than the main surface electrode (30, 32, 124), and the sealing insulator (71) is thicker than the insulating film (38).
[A19] The semiconductor device (1A to 1G) according to any one of A15 to A18, wherein the fillers (75) include fillers (75c) thicker than the insulating film (38).
[A20] The semiconductor device (1A to 1G) according to any one of A1 to A19, wherein the chip (2) includes a monocrystal of a wide bandgap semiconductor.
[B1] A manufacturing method for a semiconductor device (1A to 1G) comprising: a step of preparing a wafer structure (80) that includes a wafer (81) having a main surface (82) and a main surface electrode (30, 32, 124) arranged on the main surface (82); a step of forming a terminal electrode (50, 60, 126) on the main surface electrode (30, 32, 124); and a step of forming a sealing insulator (71) that covers a periphery of the terminal electrode (50, 60, 126) on the main surface (82) such as to expose a part of the terminal electrode (50, 60, 126), and that includes a matrix resin (74) and fillers (75) added into the matrix resin (74) such that a ratio of a total cross-sectional area with respect to a unit cross-sectional area is higher than a ratio of a cross-sectional area of the matrix resin (74) with respect to the unit cross-sectional area.
[B2] The manufacturing method for the semiconductor device (1A to 1G) according to B1, wherein the fillers (75) are added into the matrix resin (74) such that the ratio of the total cross-sectional area is not less than 60%.
[B3] The manufacturing method for the semiconductor device (1A to 1G) according to B1 or B2, wherein the forming step of the sealing insulator (71) includes a step of supplying, onto the main surface (82), a sealant (92) including the matrix resin (74) consisting of a thermosetting resin and the fillers (75), and a step of forming the sealing insulator (71) by thermosetting the sealant (92).
[B4] The manufacturing method for the semiconductor device (1A to 1G) according to B3, wherein the forming step of the sealing insulator (71) includes a step of supplying the sealant (92) onto the main surface (82) such as to cover a whole region of the terminal electrode (50, 60, 126), and a step of partially removing the sealing insulator (71) until a part of the terminal electrode (50, 60, 126) is exposed after the thermosetting step of the sealant (92).
[B5] The manufacturing method for the semiconductor device (1A to 1G) according to any one of B1 to B4, wherein the forming step of the terminal electrode (50, 60, 126) includes a step of forming the terminal electrode (50, 60, 126) thicker than the main surface electrode (30, 32, 124), and the forming step of the sealing insulator (71) includes a step of forming the sealing insulator (71) thicker than the main surface electrode (30, 32, 124).
[B6] The manufacturing method for the semiconductor device (1A to 1G) according to any one of B1 to B5, further comprising: a step of thinning the wafer (81) after the forming step of the sealing insulator (71).
[B7] The manufacturing method for the semiconductor device (1A to 1G) according to B6, wherein the thinning step of the wafer (81) includes a step of thinning the wafer (81) until a thickness of the wafer (81) becomes less than a thickness of the sealing insulator (71).
[B8] The manufacturing method for the semiconductor device (1A to 1G) according to any one of B1 to B7, wherein the fillers (75) are composed of one of or both of spherical objects and indeterminate objects.
[B9] The manufacturing method for the semiconductor device (1A to 1G) according to B8, wherein the fillers (75) are composed of the spherical objects.
[B10] The manufacturing method for the semiconductor device (1A to 1G) according to any one of B1 to B9, wherein the fillers (75) include at least one of ceramics, oxides, and nitrides.
[B11] The manufacturing method for the semiconductor device (1A to 1G) according to any one of B1 to B10, wherein the sealing insulator (71) includes the fillers (75) having different particle sizes.
[B12] The manufacturing method for the semiconductor device (1A to 1G) according to any one of B1 to B11, wherein the fillers (75) each have a particle size of not less than 1 nm and not more than 50 μm.
[B13] The manufacturing method for the semiconductor device (1A to 1G) according to any one of B1 to B12, wherein the fillers (75) include fillers (75a) thinner than the main surface electrode (30, 32, 124) and fillers (75b) thicker than the main surface electrode (30, 32, 124).
[B14] The manufacturing method for the semiconductor device (1A to 1G) according to any one of B1 to B13, wherein the forming step of the terminal electrode (50, 60, 126) includes: a step of forming a conductor film (89) covering the main surface electrode (30, 32, 124); a step of forming, on the conductor film (89), a mask (90) that exposes a portion of the conductor film (89) that covers the main surface electrode (30, 32, 124); a step of depositing a conductor (91) on a portion of the conductor film (89) that is exposed from the mask (90); and a step of removing the mask (90) after the deposition step of the conductor (91).
[B15] The manufacturing method for the semiconductor device (1A to 1G) according to any one of B1 to B14, further comprising: a step of preparing the wafer structure (80) that includes the wafer (81) having the main surface (82) in which a device region (86) and a scheduled cutting line (87) defining the device region (86) are set, and the main surface electrode (30, 32, 124) arranged on the main surface (82) in the device region (86); and a step of cutting the wafer (81) along the scheduled cutting line 87 after the forming step of the sealing insulator (71).
[B16] The manufacturing method for the semiconductor device (1A to 1G) according to any one of B1 to B15, further comprising: a step of forming an insulating film (38) that partially covers the main surface electrode (30, 32, 124) before the forming step of the terminal electrode (50, 60, 126); wherein the forming step of the sealing insulator (71) includes a step of forming the sealing insulator (71) that covers the terminal electrode (50, 60, 126) and the insulating film (38).
[B17] The manufacturing method for the semiconductor device (1A to 1G) according to B16, wherein the forming step of the terminal electrode (50, 60, 126) includes a step of forming the terminal electrode (50, 60, 126) having a portion directly covering the insulating film (38).
[B18] The manufacturing method for the semiconductor device (1A to 1G) according to B16 or B17, wherein the forming step of the insulating film (38) includes a step of forming the insulating film (38) including any one of or both of an inorganic insulating film (42) and an organic insulating film (43).
[B19] The manufacturing method for the semiconductor device (1A to 1G) according to any one of B1 or B18, wherein the wafer (81) has a laminated structure including a substrate (7) and an epitaxial layer (6), and has the main surface (82) formed by the epitaxial layer (6).
[B20] The manufacturing method for the semiconductor device (1A to 1G) according to any one of B1 to B19, wherein the wafer (81) includes a monocrystal of a wide bandgap semiconductor.

While embodiments of the present invention have been described in detail above, those are merely specific examples used to clarify the technical contents, and the present invention should not be interpreted as being limited only to those specific examples, and the spirit and scope of the present invention shall be limited only by the appended Claims.

What is claimed is:

1. A semiconductor device comprising:
a chip that has a main surface;
a main surface electrode that is arranged on the main surface;
a terminal electrode that is arranged on the main surface electrode; and
a sealing insulator that covers a periphery of the terminal electrode on the main surface such as to expose a part of the terminal electrode, and that includes a matrix resin and fillers added into the matrix resin such that a ratio of a total cross-sectional area with respect to a unit cross-sectional area is higher than a ratio of a cross-sectional area of the matrix resin with respect to the unit cross-sectional area.

2. The semiconductor device according to claim 1,
wherein the fillers are added into the matrix resin such that the ratio of the total cross-sectional area is not less than 60%.

3. The semiconductor device according to claim 1,
wherein the terminal electrode is thicker than the main surface electrode, and
the sealing insulator is thicker than the main surface electrode.

4. The semiconductor device according to claim 1,
wherein the terminal electrode is thicker than the chip, and the sealing insulator is thicker than the chip.

5. The semiconductor device according to claim 1,
wherein the matrix resin consists of a thermosetting resin.

6. The semiconductor device according to claim 1,
wherein the fillers are composed of one of or both of spherical objects and indeterminate objects.

7. The semiconductor device according to claim 6,
wherein the fillers are composed of the spherical objects.

8. The semiconductor device according to claim 1,
wherein the fillers include at least one of ceramics, oxides, and nitrides.

9. The semiconductor device according to claim 1,
wherein the sealing insulator includes the fillers having different particle sizes.

10. The semiconductor device according to claim 1,
wherein the fillers each have a particle size of not less than 1 nm and not more than 50 μm.

11. The semiconductor device according to claim 1,
wherein the fillers include fillers thinner than the main surface electrode and fillers thicker than the main surface electrode.

12. The semiconductor device according to claim 1,
wherein the terminal electrode has a terminal surface and a terminal side wall, and
the sealing insulator exposes the terminal surface and covers the terminal side wall.

13. The semiconductor device according to claim 12,
wherein the sealing insulator has an insulating main surface that forms a single flat surface with the terminal surface.

14. The semiconductor device according to claim 1,
wherein the chip has a side surface, and
the sealing insulator has an insulating side wall that forms a single flat surface with the side surface.

15. The semiconductor device according to claim 1, further comprising:
an insulating film that partially covers the main surface electrode;
wherein the sealing insulator has a portion that directly covers the insulating film.

16. The semiconductor device according to claim 15,
wherein the terminal electrode has a portion that directly covers the insulating film.

17. The semiconductor device according to claim 15,
wherein the insulating film includes at least one of an inorganic insulating film and an organic insulating film.

18. The semiconductor device according to claim 15,
wherein the insulating film is thicker than the main surface electrode, and
the sealing insulator is thicker than the insulating film.

19. The semiconductor device according to claim 15,
wherein the fillers include fillers thicker than the insulating film.

20. The semiconductor device according to claim 1,
wherein the chip includes a monocrystal of a wide bandgap semiconductor.
